(19) United States
(12) Patent Application Publication
(10) Pub. No.: US 2026/0123210 A1
(43) Pub. Date: Apr. 30, 2026

(54) DISPLAY DEVICE AND ELECTRONIC DEVICE INCLUDING THE SAME

(71) Applicant: Samsung Display Co., Ltd., Yongin-si (KR)

(72) Inventors: JUNHYUN PARK, Yongin-si (KR); SUNKWUN SON, Yongin-si (KR); CHEOL-GON LEE, Yongin-si (KR); NAHYEON CHA, Yongin-si (KR)

(21) Appl. No.: 19/213,769

(22) Filed: May 20, 2025

(30) Foreign Application Priority Data
Oct. 30, 2024 (KR) 10-2024-0150608

(51) Int. Cl. H10K 59/131; G09G 3/3233; H10K 59/35

(52) U.S. Cl. CPC H10K 59/131; G09G 3/3233; H10K 59/353; G09G 2300/0426; G09G 2300/0819; G09G 2300/0852; G09G 2300/0861; G09G 2330/021

(57) ABSTRACT

A display device includes: a pixel circuit layer including a first pixel circuit, a second pixel circuit, and a third pixel circuit that are disposed in a same row; a first light-emitting element configured to emit light of a first color, and including: a first pixel electrode on the pixel circuit layer and electrically connected to the first pixel circuit; and a first light-emitting layer on the first pixel electrode; a second light-emitting element configured to emit light of the first color, and including: a second pixel electrode on the pixel circuit layer and electrically connected to the second pixel circuit; and a second light-emitting layer on the second pixel electrode; a third light-emitting element configured to emit light of a second color different from the first color, and including: a third pixel electrode on the pixel circuit layer, electrically connected to the third pixel circuit.

### CROSS-REFERENCE TO RELATED APPLICATION

The present application claims priority to and the benefit of Korean Patent Application No. 10-2024-0150608, filed on Oct. 30, 2024, in the Korean Intellectual Property Office, the entire disclosure of which is incorporated by reference herein.

### BACKGROUND

### 1. Field

The present disclosure relates to a display device and an electronic device including the same. More particularly, the present disclosure relates to a display device providing an visual information and the electronic device including the same.

### 2. Description of the Related Art

An electronic device such as smart phone, digital camera, notebook computer, navigation system, monitor, and smart television that provide images to users include display devices for displaying images. The display devices generate images and provide the generated images to users through a display screen.

The display devices include a plurality of pixels for generating images and a driver for driving the pixels. Each of the pixels includes a light-emitting element and a pixel circuit connected to the light-emitting element. The pixel circuit is driven by a driver so that the light-emitting element emits light. A layout design of the pixel circuits and light-emitting elements is being developed in a direction that may maximize the light-emitting efficiency while increasing resolution in a limited space.

### SUMMARY

Embodiments of the present disclosure provide a display device capable of reducing power consumption.

Embodiments of the present disclosure also provide an electronic device including the display device.

In one or more embodiments, a display device comprising: a pixel circuit layer comprising a first pixel circuit, a second pixel circuit, and a third pixel circuit that are disposed in a same row; a first light-emitting element configured to emit light of a first color, and comprising: a first pixel electrode on the pixel circuit layer and electrically connected to the first pixel circuit; and a first light-emitting layer on the first pixel electrode; a second light-emitting element configured to emit light of the first color, and comprising: a second pixel electrode on the pixel circuit layer and electrically connected to the second pixel circuit; and a second light-emitting layer on the second pixel electrode; a third light-emitting element configured to emit light of a second color different from the first color, and comprising: a third pixel electrode on the pixel circuit layer, electrically connected to the third pixel circuit, and overlapping each of the first pixel circuit, the second pixel circuit, and the third pixel circuit in a plan view; and a third light-emitting layer on the third pixel electrode; a first write gate line extending along a first direction in the pixel circuit layer, and configured to provide a first write gate signal to the first pixel circuit and the third pixel circuit; and a second write gate line extending along the first direction in the pixel circuit layer, and configured to provide a second write gate signal applied at a different timing from an application timing of the first write gate signal to the second pixel circuit.

In one or more embodiments, the third pixel electrode comprises: a first main portion overlapping the third pixel circuit in a plan view; and a first extending portion extending from the first main portion, and overlapping each of the first pixel circuit, the second pixel circuit, and the third pixel circuit in a plan view.

In one or more embodiments, the pixel circuit layer further comprises: a fourth pixel circuit electrically connected to the second write gate line; a fifth pixel circuit electrically connected to the first write gate line; and a sixth pixel circuit electrically connected to the second write gate line.

In one or more embodiments, the second pixel circuit, the first pixel circuit, the third pixel circuit, the fourth pixel circuit, the fifth pixel circuit, and the sixth pixel circuit are repeatedly arranged along the first direction in an order of the second pixel circuit, the first pixel circuit, the third pixel circuit, the fourth pixel circuit, the fifth pixel circuit, and the sixth pixel circuit.

In one or more embodiments, the display device further comprising: a fourth light-emitting element configured to emit light of the second color, and comprising: a fourth pixel electrode on the pixel circuit layer, and electrically connected to the fourth pixel circuit; and a fourth light-emitting layer on the fourth pixel electrode; a fifth light-emitting element configured to emit light of a third color different from the first color and the second color, and comprising: a fifth pixel electrode disposed on the pixel circuit layer, and electrically connected to the fifth pixel circuit; and a fifth light-emitting layer on the fifth pixel electrode; and a sixth light-emitting element configured to emit light of the third color, and comprising: a sixth pixel electrode on the pixel circuit layer, and electrically connected to the sixth pixel circuit; and a sixth light-emitting layer on the sixth pixel electrode.

In one or more embodiments, the fifth pixel electrode comprises: a second main portion overlapping the sixth pixel circuit in a plan view; and a second extending portion extending from the second main portion, and overlapping each of the fourth pixel circuit and the fifth pixel circuit.

In one or more embodiments, the second extending portion of the fourth pixel electrode is spaced from the fifth pixel electrode in a plan view, and extends along at least a portion of the fifth pixel electrode.

In one or more embodiments, the sixth pixel electrode comprises: a third main portion overlapping each of the first pixel circuit adjacent to the sixth pixel circuit, and the second pixel circuit; and a third extending portion extending from the third main portion, and overlapping each of the second pixel circuit and the sixth pixel circuit.

In one or more embodiments, the first extending portion of the third pixel electrode is spaced from the third main portion of the sixth pixel electrode in a plan view, and extends along at least a portion of the third main portion.

In one or more embodiments, the display device further comprising: a plurality of first auxiliary electrodes on the pixel circuit layer, adjacent to the sixth pixel electrode, and arranged along a second direction crossing the first direction; and a pixel defining layer on the first auxiliary electrodes, wherein a hole is defined in the pixel defining layer, and the hole exposes an upper surface of at least one of a first auxiliary electrode from among the plurality of the first auxiliary electrodes.

In one or more embodiments, the display device further comprising: a plurality of second auxiliary electrodes on the pixel circuit layer, adjacent to the fifth pixel circuit, and arranged along the second direction, wherein the pixel defining layer covers an upper surface of each of the second auxiliary electrodes entirely.

In one or more embodiments, the display device further comprising: a first data line extending along a second direction crossing the first direction in the pixel circuit layer, and electrically connected to each of the first pixel circuit and the second pixel circuit; a second data line extending along the second direction in the pixel circuit layer, and electrically connected to the third pixel circuit and the fourth pixel circuit; and a third data line extending along the second direction in the pixel circuit layer, and electrically connected to the fifth pixel circuit and sixth pixel circuit.

In one or more embodiments, wherein the first data line is between the first pixel circuit and the second pixel circuit that are adjacent to each other, in a plan view, wherein the second data line is between the third pixel circuit and the fourth pixel circuit that are adjacent to each other, in a plan view, and wherein the third data line is between the fifth pixel circuit and the sixth pixel circuit that are adjacent to each other, in a plan view.

In one or more embodiments, a display device comprising: a pixel circuit layer comprising a first pixel circuit, a second pixel circuit spaced from the first pixel circuit in a first direction, a third pixel circuit, a fourth pixel circuit, a fifth pixel circuit, and a sixth pixel circuit that are located between the first pixel circuit and the second pixel circuit and arranged along the first direction orderly; a first light-emitting element configured to emit light of a first color, and comprising: a first pixel electrode on the pixel circuit layer and electrically connected to the first pixel circuit; and a first light-emitting layer on the first pixel electrode; a second light-emitting element configured to emit light of the first color, and comprising: a second pixel electrode on the pixel circuit layer, electrically connected to the second pixel circuit, and overlapping each of the second pixel circuit, the fifth pixel circuit, and the sixth pixel circuit in a plan view; and a second light-emitting layer on the second pixel electrode; and a third light-emitting element configured to emit light of a second color different from the first color, and comprising: a third pixel electrode on the pixel circuit layer and electrically connected to the third pixel circuit; and a third light-emitting layer on the third pixel electrode.

In one or more embodiments, the second pixel electrode comprises: a main portion overlapping the second pixel circuit in a plan view; and an extending portion extending from the main portion along the first direction, and overlapping each of the second pixel circuit, the fifth pixel circuit, and the sixth pixel circuit in a plan view.

In one or more embodiments, the display device further comprising: a first write gate line extending along the first direction in the pixel circuit layer, and configured to provide a first write gate signal to each of the first pixel circuit, the third pixel circuit, and the fifth pixel circuit; and a second write gate line extending along the first direction in the pixel circuit layer, and configured to a second write gate signal applied at a different timing from an application timing of the first write gate signal to the second pixel circuit, the fourth pixel circuit, and the sixth pixel circuit.

In one or more embodiments, the display device further comprising: a first data line extending along a second direction crossing the first direction in the pixel circuit layer, and electrically connected to each of the first pixel circuit and the second pixel circuit; a second data line extending along the second direction in the pixel circuit layer, and electrically connected to each of the third pixel circuit and the fourth pixel circuit; and a third data line extending along the second direction in the pixel circuit layer, and electrically connected to each of the fifth pixel circuit and the sixth pixel circuit.

In one or more embodiments, the display device further comprising: a fourth light-emitting element configured to emit light of the second color, and comprising: a fourth pixel electrode on the pixel circuit layer and electrically connected to the fourth pixel circuit; and a fourth light-emitting layer on the fourth pixel electrode; a fifth light-emitting element configured to emit light of a third color different from the first color and the second color, and comprising: a fifth pixel electrode on the pixel circuit layer and electrically connected to the fifth pixel circuit; and a fifth light-emitting layer on the fifth pixel electrode; and a sixth light-emitting element configured to emit light of the third color, and comprising: a sixth pixel electrode on the pixel circuit layer and electrically connected to the sixth pixel circuit; and a sixth light-emitting layer on the sixth pixel electrode.

In one or more embodiments, the display device further comprising: a plurality of first auxiliary electrodes on the pixel circuit layer, adjacent to the fifth pixel electrode, and arranged along a second direction crossing the first direction; a plurality of second auxiliary electrodes on the pixel circuit layer, adjacent to the sixth pixel electrode, and arranged along the second direction; and a pixel defining layer on the first auxiliary electrodes and the second auxiliary electrodes, wherein a hole is defined in the pixel defining layer, and the hole exposes an upper surface of at least one of a first auxiliary electrode among the first auxiliary electrodes, wherein the pixel defining layer covers an upper surface of each of the second auxiliary electrodes entirely, and wherein a virtual line connecting a center of the fifth pixel electrode and a center of the sixth pixel electrode has a zigzag shape along the first direction.

In one or more embodiments, an electronic device comprising: a processor configured to output an input image data and an input control signal; and a display device configured to drive based on the input image data and the input control data, and the display device comprising: a pixel circuit layer comprising a first pixel circuit, a second pixel circuit, and a third pixel circuit that are arranged in a same row; a first light-emitting element configured to emit light of a first color, and comprising: a first pixel electrode on the pixel circuit layer and electrically connected to the first pixel circuit and a first light-emitting layer on the first pixel electrode; a second light-emitting element configured to emit light of the first color comprising a second pixel electrode on the pixel circuit layer and electrically connected to the second pixel circuit and a second light-emitting layer on the second pixel electrode; a third light-emitting element configured to emit light of a second color different from the first color, and comprising a third pixel electrode on the pixel circuit layer, electrically connected to the third pixel circuit, and overlapping each of the first pixel circuit, the second pixel circuit, and the third pixel circuit in a plan view and a third light-emitting layer on the third pixel electrode; a first write gate line extending along a first direction in the pixel circuit layer, and configured to provide a first write gate signal to the first pixel circuit and the third pixel circuit; and

In one or more embodiments, the display device may further include a plurality of auxiliary electrodes and a pixel defining layer. The plurality of auxiliary electrodes may be disposed on the pixel circuit layer, may be adjacent to the fifth pixel electrode, and may be disposed along a second direction crossing the first direction. The pixel defining layer may be disposed on the auxiliary electrodes. A hole may be defined in the pixel defining layer, and the hole may expose an upper surface of at least one of an auxiliary electrode among the auxiliary electrodes. A virtual line connecting a center of the fifth pixel electrode and a center of the sixth pixel electrode may be parallel to the first direction.

In a display device according to embodiments of the present disclosure, a data voltage may be provided to each of pixels included in a first pixel group through a first write gate line to which a first write gate signal is applied. In addition, the data voltage may be provided to each of the pixels included in a second pixel group disposed in a same row as the pixels included in the first pixel group through a second write gate line to which a second write gate signal is applied at a different timing at which the first write gate signal is applied. Accordingly, the display device may selectively output the data voltage to one of a plurality of pixels disposed in a same row. Accordingly, a power consumption efficiency of the display device may be improved, and a number of pixels disposed in a display area of the display device may be increased, so that a display quality may be improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to one or more embodiments of the present disclosure.

FIG. 2 is a view illustrating a portion of the display device of FIG. 1.

FIG. 3 is a circuit diagram illustrating pixels included in a display panel of FIG. 1.

FIG. 4 is a circuit diagram illustrating an example of an operation of the pixels of FIG. 3.

FIG. 5 is a circuit diagram illustrating another example of an operation of the pixels of FIG. 3.

FIGS. 6, 7, and 8 are layout diagrams illustrating an example of an arrangement of components of the pixels included in the display panel of FIG. 1.

FIG. 9 is a cross-sectional view illustrating each of A1, A2, and A3 areas of FIG. 8.

FIG. 10 is a layout diagram illustrating another example of an arrangement of components of the pixels included in the display panel of FIG. 1.

FIGS. 11 and 12 are layout diagrams illustrating still another example of an arrangement of components of the pixels included in the display panel of FIG. 1.

FIG. 13 is a plan view explaining for an example of an arrangement of a pixel electrode and an auxiliary electrode of FIG. 12.

FIG. 14 is a plan view explaining for another example of an arrangement of a pixel electrode and an auxiliary electrode of FIG. 12.

FIG. 15 is a block diagram illustrating an electronic device according to one or more embodiments.

FIG. 16 is a view illustrating an example a display device being implemented as a smart phone.

### DETAILED DESCRIPTION

The present disclosure now will be described more fully hereinafter with reference to the accompanying drawings, in which embodiments of the present disclosure are shown. The present disclosure may, however, be embodied in many different forms and should not be construed as limited to the embodiments set forth herein.

Rather, these embodiments are provided so that the present disclosure will be thorough and complete, and will fully convey the scope of the present disclosure to those skilled in the art. Like reference numerals refer to like elements throughout.

It will be understood that, although the terms first, second, third, and the like. may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the present disclosure.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, for example, those defined in commonly used dictionaries, should be interpreted as having a meaning that is consistent with their meaning in the context of the relevant art and will not be interpreted in an idealized or overly formal sense unless expressly so defined herein.

All methods described herein may be performed in a suitable order unless otherwise indicated herein or otherwise clearly contradicted by context. The use of any and all examples, or exemplary language (e.g., “for example”), is intended merely to better illustrate the present disclosure and does not pose a limitation on the scope of the present disclosure unless otherwise claimed. No language in the specification should be construed as indicating any non-claimed element as essential to the practice of the present disclosure as used herein.

Hereinafter, display devices and electronic devices including the same in accordance with one or more embodiments will be described in more detail with reference to the accompanying drawings. The same reference numerals are used for the same components in the drawings, and redundant descriptions of the same components will be omitted.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

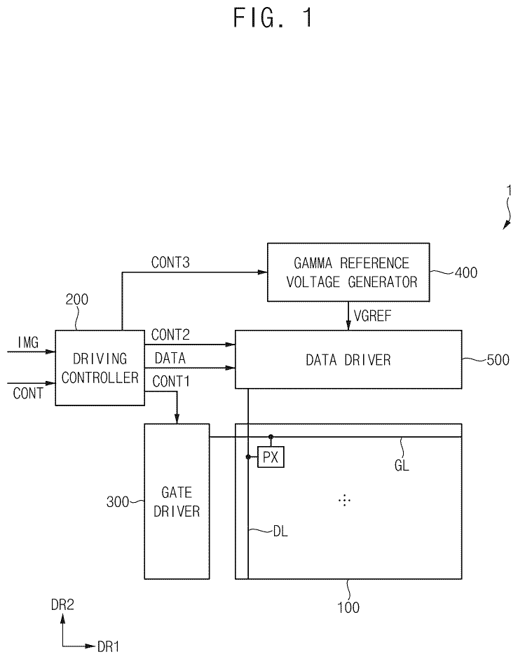

FIG. 1 is a block diagram illustrating a display device according to one or more embodiments of the present disclosure.

Referring to FIG. 1, a display device 1 according to one or more embodiments of the present disclosure may include a display panel 100 and a display panel driver. The display panel driver may include a driving controller 200, a gate driver 300, a gamma reference voltage generator 400, and a data driver 500.

In one or more embodiments, the driving controller 200 and the data driver 500 may be formed integrally. In one or more embodiments, the driving controller 200, the gamma reference voltage generator 400, and the data driver 500 may be formed integrally. For example, a drive module in which the driving controller 200 and the data driver 500 are formed integrally may be referred to as a timing controller embedded data driver (TED).

The display panel 100 may include a display portion defined as an area for displaying an image and a peripheral portion adjacent to the display portion. In one or more embodiments, the display panel 100 may be an organic light-emitting diode (OLED) display panel including an organic light-emitting diode (OLED). In another embodiment, the display panel 100 may be an organic light-emitting diode (OLED) display panel including an organic light-emitting diode (OLED) and a quantum dot color filter. In still another embodiment, the display panel 100 may be a quantum-dot nano light-emitting diode display panel including a nano light-emitting diode and a quantum-dot color filter. However, a type of the display panel 100 according to one or more embodiments of the present disclosure may not be necessarily limited thereto.

The display panel 100 may include a plurality of pixels PX, a plurality of gate lines GL, and a plurality of data lines DL. Each of the plurality of pixels PX, the plurality of gate lines GL, and the plurality of data lines DL may be disposed in the display portion of the display panel 100. The display panel driver may be disposed in the peripheral portion of the display panel 100.

In the present disclosure, a plane may be defined by a first direction DR1 and a second direction DR2 crossing the first direction DR1. For example, the second direction DR2 may be perpendicular to the first direction DR1. In addition, a third direction DR3 may be perpendicular to the plane.

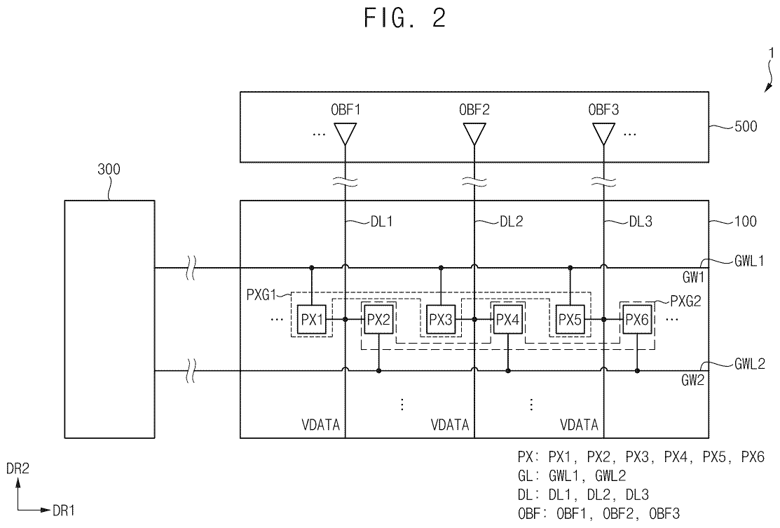

The plurality of pixels PX may be disposed in a matrix form including a plurality of pixel rows and a plurality of pixel columns. The plurality of pixels PX may be disposed along the first direction DR1 and the second direction DR2. Each of the plurality of pixels PX may emit light of a different color. For example, from among the plurality of pixels PX, one pixel (e.g., the first pixel PX1 or the second pixel PX2 of FIG. 2) may emit light of a first color, another pixel (e.g., the third pixel PX3 or the fourth pixel PX4 of FIG. 2) of the plurality of pixels PX may emit light of a second color, and still another pixel (e.g., the fifth pixel PX5 or the sixth pixel PX6 of FIG. 2) of the plurality of pixels PX may emit light of a third color. In one or more embodiments, light of the first color may be light of green color, light of the second color may be light of red color, and light of the third color may be light of blue color. However, a color of the light emitted by each of the plurality of pixels PX according to one or more embodiments of the present disclosure may not be necessarily limited thereto. For example, each of the plurality of pixels PX may be combined to emit light of magenta color, light of cyan color, and light of yellow color.

Each of the plurality of gate lines GL may extend along the first direction DR1. Each of the plurality of gate lines GL may be spaced (e.g., spaced apart) from each other along the second direction DR2. Each of the plurality of data lines DL may extend along the second direction DR2. Each of the plurality of data lines DL may be spaced (e.g., spaced apart) from each other along the first direction DR1.

In one or more embodiments, each of the plurality of pixels PX may be electrically connected to at least one gate line of the plurality of gate lines GL and at least one data line of the plurality of data lines DL.

The driving controller 200 may receive an input image data IMG and an input control signal CONT from an external device (e.g., a host processor such as a graphic processing unit (GPU)). In one or more embodiments, the input image data IMG may include red image data, green image data, and blue image data. In one or more embodiments, the input image data IMG may further include white image data. In another embodiment, the input image data IMG may include magenta image data, yellow image data, and/or cyan image data. The input control signal CONT may include a master clock signal and a data enable signal. The input control signal CONT may further include a vertical synchronization signal and a horizontal synchronization signal.

The driving controller 200 may generate a gate control signal CONT1, a data control signal CONT2, a gamma control signal CONT3, and a data signal DATA based on the input image data IMG and the input control signal CONT.

The driving controller 200 may generate a gate control signal CONT1 for controlling an operation of the gate driver 300 based on the input control signal CONT. The driving controller 200 may output a gate control signal CONT1 to the gate driver 300. The gate control signal CONT1 may include a vertical start signal and a gate clock signal.

The driving controller 200 may generate a data control signal CONT2 for controlling an operation of the data driver 500 based on the input control signal CONT. The driving controller 200 may output the data control signal CONT2 to the data driver 500. The data control signal CONT2 may include a horizontal start signal and a load signal.

The driving controller 200 may generate a data signal DATA based on the input image data IMG. The driving controller 200 may output the data signal DATA to the data driver 500.

The driving controller 200 may generate a gamma control signal CONT3 for controlling an operation of the gamma reference voltage generator 400 based on the input control signal CONT. The driving controller 200 may output the gamma control signal CONT3 to the gamma reference voltage generator 400.

The gate driver 300 may generate gate output signals for driving a plurality of gate lines GL in response to the gate control signal CONT1 input from the driving controller 200.

The gamma reference voltage generator 400 may generate a gamma reference voltage VGREF in response to the gamma control signal CONT3 input from the driving controller 200. The gamma reference voltage generator 400 may provide the gamma reference voltage VGREF to the data driver 500. In one or more embodiments, the gamma reference voltage generator 400 may be disposed in the driving controller 200 or may be disposed in the data driver 500.

The data driver 500 may receive a data control signal CONT2 and the data signal DATA from the driving controller 200. The data driver 500 may receive the gamma reference voltage VGREF from the gamma reference voltage generator 400. The data driver 500 may generate a data voltage (e.g., the data voltage VDATA of FIG. 2). For example, the data driver 500 may convert the data signal DATA into the data voltage in an analog form using the gamma reference voltage VGREF. The data driver 500 may output the data voltage to each of the plurality of data lines DL.

FIG. 2 is a view illustrating a portion of the display device of FIG. 1. For example, FIG. 2 is a view illustrating a portion of each of the display panel 100, the gate driver 300, and the data driver 500 included in the display device 1.

Referring to FIGS. 1 and 2, the plurality of pixels PX included in the display panel 100 may include a first pixel PX1, a second pixel PX2, a third pixel PX3, a fourth pixel PX4, a fifth pixel PX5, and a sixth pixel PX6. The first pixel PX1, the third pixel PX3, and the fifth pixel PX5 may define a first pixel group PXG1. The second pixel PX2, the fourth pixel PX4, and the sixth pixel PX6 may define a second pixel group PXG2.

The first pixel PX1 and the second pixel PX2 may emit light of a same color. For example, each of the first pixel PX1 and the second pixel PX2 may emit light of the first color. The third pixel PX3 and the fourth pixel PX4 may emit light of a same color. For example, the third pixel PX3 and the fourth pixel PX4 may each emit light of the second color. The fifth pixel PX5 and the sixth pixel PX6 may emit light of a same color. For example, the fifth pixel PX5 and the sixth pixel PX6 may each emit light of the third color. In one or more embodiments, the light of the first color, the light of the second color, and the light of the third color may have different colors.

In one or more embodiments, the pixels PX may be disposed in a row repeatedly with a plurality of groups, including the first pixel PX1, the second pixel PX2, the third pixel PX3, the fourth pixel PX4, the fifth pixel PX5, and the sixth pixel PX6 as one of a group.

The plurality of gate lines GL may include a first write gate line GWL1 and a second write gate line GWL2. The first write gate line GWL1 may be electrically connected to pixels included in the first pixel group PXG1. For example, the first write gate line GWL1 may be electrically connected to each of the first pixel PX1, the third pixel PX3, and the fifth pixel PX5. The second write gate line GWL2 may be electrically connected to pixels included in the second pixel group PXG2. For example, the second write gate line GWL2 may be electrically connected to each of the second pixel PX2, the fourth pixel PX4, and the sixth pixel PX6.

Specifically, a portion of the pixels disposed along one row (e.g., the first pixel PX1, the third pixel PX3, and the fifth pixel PX5) may be electrically connected to the first write gate line GWL1. In addition, another portion of pixels (e.g., the second pixel PX2, the fourth pixel PX4, and the sixth pixel PX6) disposed along the one row may be electrically connected to the second write gate line GWL2.

That is, the first pixel group PXG1 may be defined as a group including pixels that are referred to as an odd-numbered in the present disclosure and receive the first write gate signal GW1, and the second pixel group PXG2 may be defined as a group including pixels that are referred to as an even-numbered in the present disclosure and receive the second write gate signal GW2.

In one or more embodiments, the first write gate line GWL1 and the second write gate line GWL2 may disposed along one low, and extend along the first direction DR1 by disposing the pixels PX, which is electrically connected to the first write gate line GWL1 and the second write gate line GWL2, between the first write gate line GWL1 and the second write gate line GWL2. However, an arrangement of each of the first write gate line GWL1 and the second write gate line GWL2 according to the present disclosure may not be necessarily limited thereto, and both the first write gate line GWL1 and the second write gate line GWL2 may be disposed in the second direction DR2 or in an opposite direction of the second direction DR2 from each of the pixels PX electrically connected to the first write gate line GWL1 and the second write gate line GWL2.

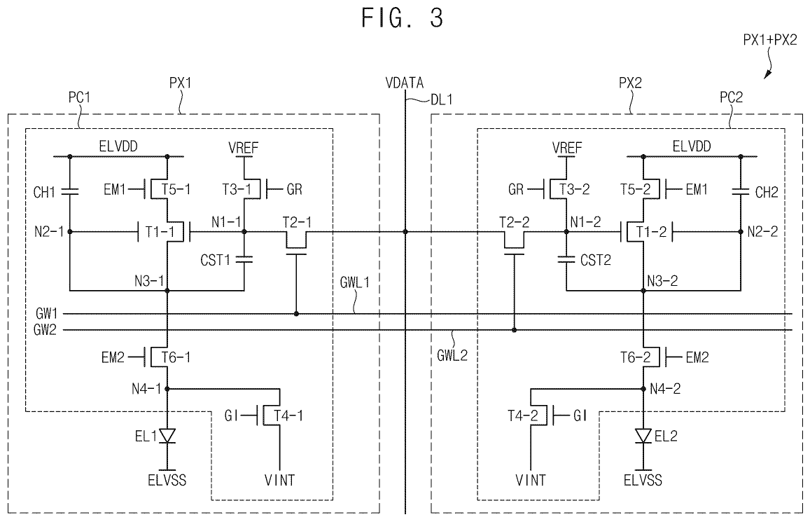

A first write gate signal GW1 may be applied to the first write gate line GWL1. A second write gate signal GW2 may be applied to the second write gate line GWL2. The first write gate signal GW1 may have a voltage level for turning on a write transistor (e.g., a 2-1th transistor T2-1 of FIG. 3) included in each of the first pixel PX1, the third pixel PX3, and the fifth pixel PX5 during a first period in which the first write gate signal GW1 is applied. For example, the first write gate signal GW may have an activation level during the first period in which the write transistor is turned on.

The second write gate signal GW2 may have a voltage level for turning on a write transistor (e.g., a 2-2th transistor T2-2 of FIG. 3) included in each of the second pixel PX2, the fourth pixel PX4, and the sixth pixel PX6 during a second period in which the second write gate signal GW2 is applied. For example, the second write gate signal GW2 may have an activation level during the second period in which the write transistor is turned on.

In one or more embodiments, a timing at which the first write gate signal GW1 is applied and a timing at which the second write gate signal GW2 is applied may be different from each other.

In one or more embodiments, the first write gate line GWL1 and the second write gate line GWL2 may be spaced (e.g., spaced apart) from each other in the second direction DR2. The first write gate line GWL1 may be disposed along the second direction DR2 in multiple numbers. The second write gate line GWL2 may be disposed along the second direction DR2 in multiple numbers. That is, the first write gate line GWL1 to which the first write gate signal GW1 is applied and the second write gate line GWL2 to which the second write signal GW2 is applied may be alternately and repeatedly disposed within the display panel 100.

However, the plurality of gate lines GL according to the present disclosure may not be necessarily limited thereto, and the plurality of gate lines GL may further include gate lines to which other gate signals are applied in addition to the first write gate signal GW1 and the second write gate signal GW2. For example, the plurality of gate lines GL may further include gate lines to which the gate signals of FIG. 3 (e.g., a reference signal GR, a initialization signal GI, a first light-emitting signal EM1, and a second light-emitting signal EM2 are applied.

The plurality of data lines DL may include a first data line DL1, a second data line DL2, and a third data line DL3. The data driver 500 may include a plurality of output buffers OBF that apply a data voltage VDATA to each of a plurality of data lines DL. The plurality of output buffers OBF may include a first output buffer OBF1, a second output buffer OBF2, and a third output buffer OBF3.

The first output buffer OBF1 may apply a data voltage VDATA to the first pixel PX1 and the second pixel PX2 through the first data line DL1. For example, the data voltage VDATA applied to the first data line DL1 may be provided to each of the first pixel PX1 and the second pixel PX2. Specifically, the data voltage VDATA may be provided to the first pixel PX1 during the first period, and the data voltage VDATA may be provided to the second pixel PX2 during the second period.

The second output buffer OBF2 may apply the data voltage VDATA to the third pixel PX3 and the fourth pixel PX4 through the second data line DL2. For example, the data voltage VDATA applied to the second data line DL2 may be provided to each of the third pixel PX3 and the fourth pixel PX4. Specifically, the data voltage VDATA may be provided to the third pixel PX3 during the first period, and the data voltage VDATA may be provided to the fourth pixel PX4 during the second period.

The third output buffer OBF3 may apply the data voltage VDATA to the fifth pixel PX5 and the sixth pixel PX6 through the third data line DL3. For example, the data voltage VDATA applied to the third data line DL3 may be provided to each of the fifth pixel PX5 and the sixth pixel PX6. Specifically, during the first period, the data voltage VDATA may be provided to the fifth pixel PX5, and during the second period, the data voltage VDATA may be provided to the sixth pixel PX6.

In one or more embodiments, the data driver 500 may not include a demultiplex circuit that selectively outputs the data voltage VDATA to a portion of the plurality of data lines DL. In other words, within the display device 1, the demultiplex circuit that electrically connects the plurality of output buffers OBF and the plurality of data lines DL to each other may not be disposed between the plurality of output buffers OBF and the plurality of data lines DL.

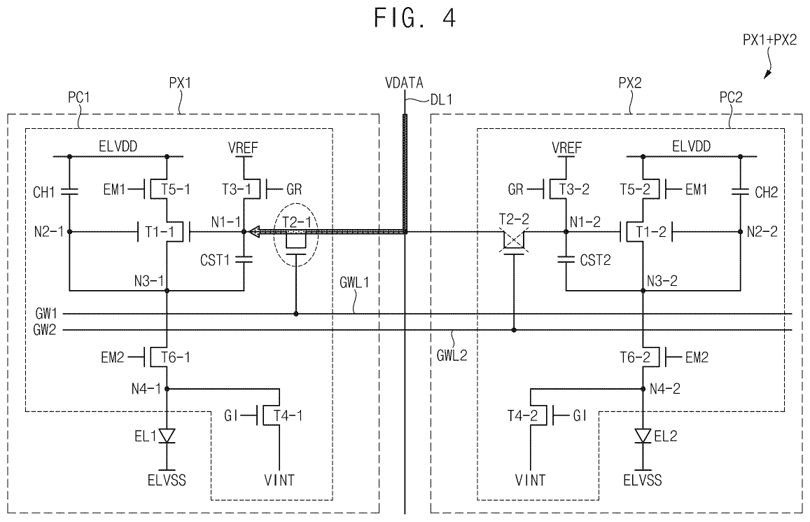

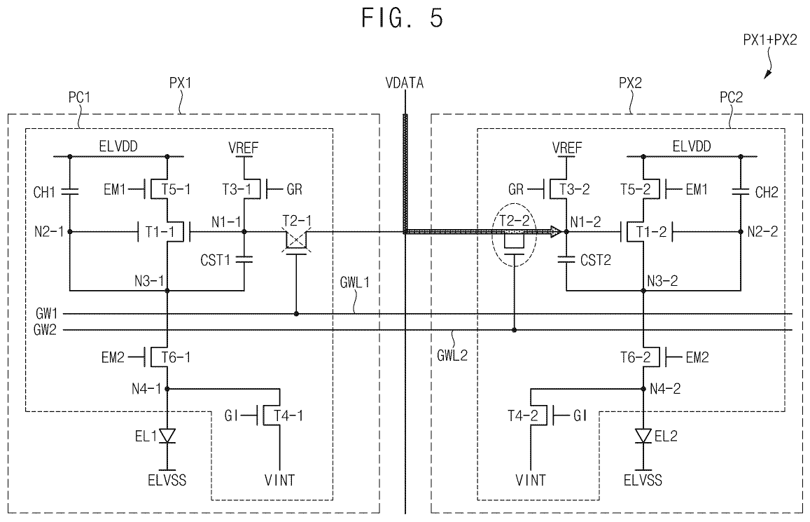

FIG. 3 is a circuit diagram illustrating pixels included in a display panel of FIG. 1. FIG. 4 is a circuit diagram illustrating an example of an operation of the pixels of FIG. 3. FIG. 5 is a circuit diagram illustrating another example of an operation of the pixels of FIG. 3.

Referring to FIGS. 3, 4, and 5, the first pixel PX1 may include a first pixel circuit PC1 and a first light-emitting element EL1. The second pixel PX2 may include a second pixel circuit PC2 and a second light-emitting element EL2. The first pixel circuit PC1 may include a 1-1th transistor T1-1, a 2-1th transistor T2-1, a 3-1th transistor T3-1, a 4-1th transistor T4-1, a 5-1th transistor T5-1, a 6-1th transistor T6-1, a first storage capacitor CST1, and a first holding capacitor CH1. The second pixel circuit PC2 may include a 1-2th transistor T1-2, a 2-2th transistor T2-2, a 3-2th transistor T3-2, a 4-2th transistor T4-2, a 5-2th transistor T5-2, a 6-2th transistor T6-2, a second storage capacitor CST2, and a second holding capacitor CH2.

The first pixel circuit PC1 and the second pixel circuit PC2 may have substantially a same structure and may perform substantially a same role, except that different write signals (e.g., the first write gate signal GW1 and the second write gate signal GW2) are applied to these circuits.

The 1-1th transistor T1-1 may include a gate terminal electrically connected to a 1-1th node N1-1, a back gate terminal electrically connected to a 2-1th node N2-1, a first terminal receiving a first power voltage ELVDD, and a second terminal electrically connected to a 3-1th node N3-1. The 1-1th transistor T1-1 may generate a current (e.g., a driving current) based on a voltage on the 1-1th node N1-1 and the 2-1th node N2-1, that is, the voltage stored in the first storage capacitor CST1. The 1-1th transistor T1-1 may be referred to as a driving transistor for generating the driving current. The 1-1th transistor T1-1 may provide the driving current to the first light-emitting element EL1.

The 1-2th transistor T1-2 may include a gate terminal electrically connected to a 1-2th node N1-2, a back gate terminal electrically connected to a 2-2th node N2-2, a first terminal receiving a first power voltage ELVDD, and a second terminal electrically connected to a 3-2th node N3-2. Structure and operation of the 1-2th transistor T1-2 may be substantially the same as or similar to the structure and operation of the 1-1th transistor T1-1.

In one or more embodiments, each of the 1-1th transistor T1-1 and the 1-2th transistor T1-2 may have a dual gate structure including a gate terminal and a back gate terminal. However, the structure of the 1-1th transistor T1-1 and the 1-2th transistor T1-2 according to the present disclosure may not be necessarily limited thereto, and each of the 1-1th transistor T1-1 and the 1-2th transistor T1-2 may not include a back gate terminal and may include a single gate terminal.

The 2-1th transistor T2-1 may include a gate terminal receiving a first write gate signal GW1, a first terminal electrically connected to the 1-1th node N1-1, and a second terminal connected to the first data line DL1. The 2-1th transistor T2-1 may be turned on or off by the first write gate signal GW1. For example, the 2-1th transistor T2-1 may apply a data voltage VDATA provided from the first data line DL1 to the 1-1th node N1-1 in response to the first write gate signal GW1. Specifically, during a first period when the first write gate signal GW1 is turned on, the data voltage VDATA may be provided to the first pixel PX1 through the 2-1th transistor T2-1. The 2-1th transistor T2-1 may be referred to as a write transistor or a scan transistor for transmitting the data voltage VDATA.

The 2-2th transistor T2-2 may include a gate terminal receiving the second write gate signal GW2, a first terminal electrically connected to the 1-2th node N1-2, and a second terminal connected to the first data line DL1. Structure and operation of the 2-2th transistor T2-2 may be substantially the same as or similar to structure and operation of the 2-1th transistor T2-1. For example, the 2-2th transistor T2-2 may be turned on or off by the second write gate signal GW2. Specifically, during a second period in which it is turned on by the second write gate signal GW2, the data voltage VDATA may be provided to the second pixel PX2 through the 2-2th transistor T2-2.

In one or more embodiments, a timing of the first period and the second period may be different from each other. For example, a starting point of a timing of the first period and a starting point of a timing of the second period may be different. Specifically, the starting point of the timing of the second period may be precede the starting point of the timing of the first period. In addition, an end point of the first period and an end point of the second period may be different. Specifically, the end point of the second period may precede the end point of the first period. In one or more embodiments, a length of the first period and the length of the second period may be equal. In other words, the second period may precede the first period. However, the present disclosure may not be necessarily limited thereto, and the second period may follow the first period.

In one or more embodiments, the first write gate signal GW1 in the first period may have an activation level. For example, the activation level may be a high level. Specifically, during a time when the first write gate signal GW1 has an activation level and the second write gate signal GW2 does not have an activation level, the data voltage VDATA may be provided to the first pixel PX1.

In one or more embodiments, the second write gate signal GW2 in the second period may have an activation level. For example, the activation level may be a high level. Specifically, during a time when the second write gate signal GW2 has an activation level and the first write gate signal GW1 does not have an activation level, the data voltage VDATA may be provided to the second pixel PX2.

However, voltage levels of each of the first write gate signal GW1 and the second write gate signal GW2 according to the present disclosure may not be necessarily limited thereto, and the voltage levels of each of the first write gate signal GW1 and the second write gate signal GW2 for turning on the write transistor may have a low level.

In one or more embodiments, the first period and the second period may partially overlap. For example, during a time when the first period has an activation level, the second period may have an activation level. Accordingly, during the time period in which the first period and the second period overlap, the 2-1th transistor T2-1 and the 2-2th transistor T2-2 are concurrently (e.g., simultaneously) turned on, and the data voltage VDATA may be concurrently (e.g., simultaneously) applied to the first pixel PX1 and the second pixel PX2 through the 2-1th transistor T2-1 and the 2-2th transistor T2-2.

The 3-1th transistor T3-1 may include a gate terminal receiving a reference signal GR, a first terminal to which a reference voltage VREF is applied, and a second terminal electrically connected to the 1-1th node N1-1. The 3-1th transistor T3-1 may be turned on or off by the reference signal GR. For example, the 3-1th transistor T3-1 may apply the reference voltage VREF to the 1-1th node N1-1 in response to the reference signal GR. The 3-1th transistor T3-1 may be referred to as a reference transistor or a reset transistor for applying the reference voltage VREF to the 1-1th node N1-1.

The 3-2th transistor T3-2 may include a gate terminal receiving a reference signal GR, a first terminal to which a reference voltage VREF is applied, and a second terminal electrically connected to the 1-2th node N1-2. Structure and operation of the 3-2th transistor T3-2 may be substantially the same as or similar to structure and operation of the 3-1th transistor T3-1.

The 4-1th transistor T4-1 may include a gate terminal receiving an initialization signal GI, a first terminal to which an initialization voltage VINT is applied, and a second terminal electrically connected to a 4-1th node N4-1. The 4-1th transistor T4-1 may be turned on or off by the initialization signal GI. For example, the 4-1th transistor T4-1 may apply the initialization voltage VINT to the 4-1th node N4-1 in response to the initialization signal GI. The 4-1th transistor T4-1 may be referred to as an initialization transistor for initializing the 4-1th node N4-1.

The 4-2th transistor T4-2 may include a gate terminal receiving an initialization signal GI, a first terminal receiving an initialization voltage VINT, and a second terminal electrically connected to a 4-2th node N4-2. Structure and operation of the 4-2th transistor T4-2 may be substantially the same as or similar to the structure and operation of the 4-1th transistor T4-1.

The 5-1th transistor T5-1 may include a gate terminal receiving a first light-emitting signal EM1, a first terminal receiving a first power voltage ELVDD, and a second terminal electrically connected to the first terminal of the 1-1th transistor T1-1. The 5-1th transistor T5-1 may be turned on or off by the first light-emitting signal EM1. For example, during a period in which the 5-1th transistor T5-1 is turned on, the 5-1th transistor T5-1 may provide the first power voltage ELVDD to the 1-1th transistor T1-1. The 5-1th transistor T5-1 may be referred to as a light-emitting transistor or an operation control transistor for forming a current path of the 1-1th transistor T1-1 from a power voltage line to which the first power voltage ELVDD is applied.

The 5-2th transistor T5-2 may include a gate terminal receiving the first light-emitting signal EM1, a first terminal receiving the first power voltage ELVDD, and a second terminal electrically connected to the first terminal of the 1-2th transistor T1-2. Structure and operation of the 5-2th transistor T5-2 may be substantially the same as or similar to the structure and operation of the 5-1th transistor T5-1.

The 6-1th transistor T6-1 may include a gate terminal receiving the second light-emitting signal EM2, a first terminal that is electrically connected to the 3-1th node N3-1, and a second terminal that is electrically connected to the 4-1th node N4-1. The 6-1th transistor T6-1 may be turned on or off by the second light-emitting signal EM2. For example, during a period in which the 6-1th transistor T6-1 is turned on, the 6-1th transistor T6-1 may provide the driving current to the first light-emitting element EL1. The 6-1th transistor T6-1 may be referred to as a light-emitting control transistor that controls the driving current provided to the first light-emitting element EL1.

The 6-2th transistor T6-2 may include a gate terminal receiving the second light-emitting signal EM2, a first terminal electrically connected to the 3-2th node N3-2, and a second terminal electrically connected to the 4-2th node N4-2. Structure and operation of the 6-2th transistor T6-2 may be substantially the same as or similar to structure and operation of the 6-1th transistor T6-1.

The first storage capacitor CST1 may include a first terminal electrically connected to the 1-1th node N1-1 and a second terminal electrically connected to the 3-1th node N3-1. The first storage capacitor CST1 may store a data voltage VDATA transmitted through the 2-1th transistor T2-1.

The second storage capacitor CST2 may include a first terminal electrically connected to the 1-2th node N1-2 and a second terminal electrically connected to the 3-2th node N3-2. Structure and operation of the second storage capacitor CST2 may be substantially the same as or similar to the structure and operation of the first storage capacitor CST1.

The first holding capacitor CH1 may include a first terminal receiving the first power voltage ELVDD and a second terminal that is electrically connected to the 2-1th node N2-1. The second terminal of the first holding capacitor CH1 may be electrically connected to the back gate terminal of the 1-1th pixel transistor T1-1. The first holding capacitor CH1 may be a capacitor for maintaining the voltage of the 2-1th node N2-1.

The second holding capacitor CH2 may include a first terminal receiving the first power voltage ELVDD and a second terminal that is electrically connected to the 2-2th node N2-2. A second terminal electrically connected may be included. Structure and operation of the second holding capacitor CH2 may be substantially the same as or similar to structure and operation of the first holding capacitor CH1.

The first light-emitting element EL1 may include a first terminal (e.g., an anode terminal) and a second terminal (e.g., a cathode terminal). The first terminal of the first light-emitting element EL1 is electrically connected to the second terminal of the 6-1th transistor T6-1, and the second terminal may be supplied with a second power voltage ELVSS. The first light-emitting element EL1 may generate light having a brightness corresponding to the driving current. In one or more embodiments, the second power voltage ELVSS may have a different voltage level from the first power voltage ELVDD. For example, a voltage level of the second power voltage ELVSS may be lower than a voltage level of the first power voltage ELVDD. However, a relationship between voltage levels of the first power supply voltage ELVDD and the second power supply voltage ELVSS according to the present disclosure may not be necessarily limited thereto.

The second light-emitting element EL2 may include a first terminal (e.g., an anode terminal) and a second terminal (e.g., a cathode terminal) electrically connected to the second terminal of the 6-2th transistor T6-2. Structure and operation of the second light-emitting element EL2 may be substantially the same as or similar to the structure and operation of the first light-emitting element EL1.

In one or more embodiments, the first light-emitting element EL1 and the second light-emitting element EL2 may emit light of a same color. For example, the first light-emitting element EL1 and the second light-emitting element EL2 may emit light of the first color from each other.

In one or more embodiments, each of the 1-1th transistor T1-1, the 1-2th transistor T1-2, the 2-1th transistor T2-1, the 2-2th transistor T2-2, the 3-1th transistor T3-1, the 3-2th transistor T3-2, the 4-1th transistor T4-1, the 4-2th transistor T4-2, the 5-1th transistor T5-1, the 5-2th transistor T5-2, the 6-1th transistor T6-1, and the 6-2th transistor T6-2 may be an NMOS.

However, a type of each of each of the 1-1th transistor T1-1, the 1-2th transistor T1-2, the 2-1th transistor T2-1, the 2-2th transistor T2-2, the 3-1th transistor T3-1, the 3-2th transistor T3-2, the 4-1th transistor T4-1, the 4-2th transistor T4-2, the 5-1th transistor T5-1, the 5-2th transistor T5-2, the 6-1th transistor T6-1, and the 6-2th transistor T6-2 according to the present disclosure may not be necessarily limited thereto, and a type of at least one from among the 1-1th transistor T1-1, the 1-2th transistor T1-2, the 2-1th transistor T2-1, the 2-2th transistor T2-2, the 3-1th transistor T3-1, the 3-2th transistor T3-2, the 4-1th transistor T4-1, the 4-2th transistor T4-2, the 5-1th transistor T5-1, the 5-2th transistor T5-2, the 6-1th transistor T6-1, and the 6-2th transistor T6-2 may be a PMOS transistor.

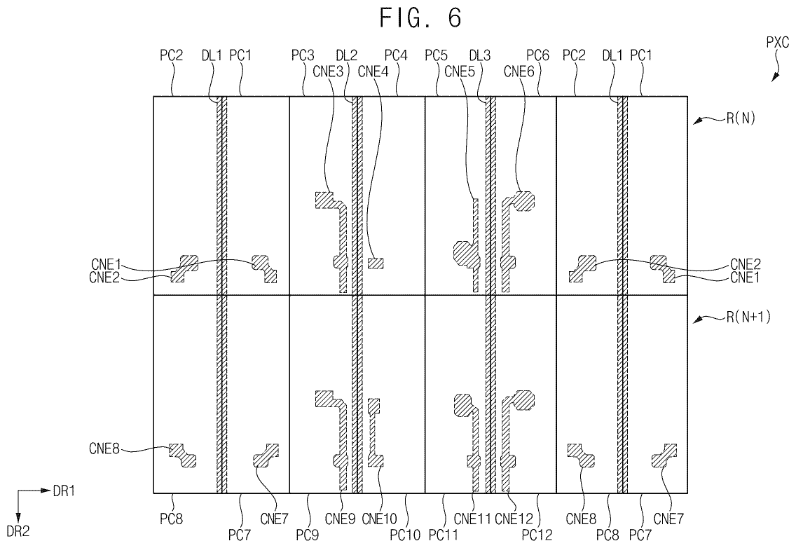

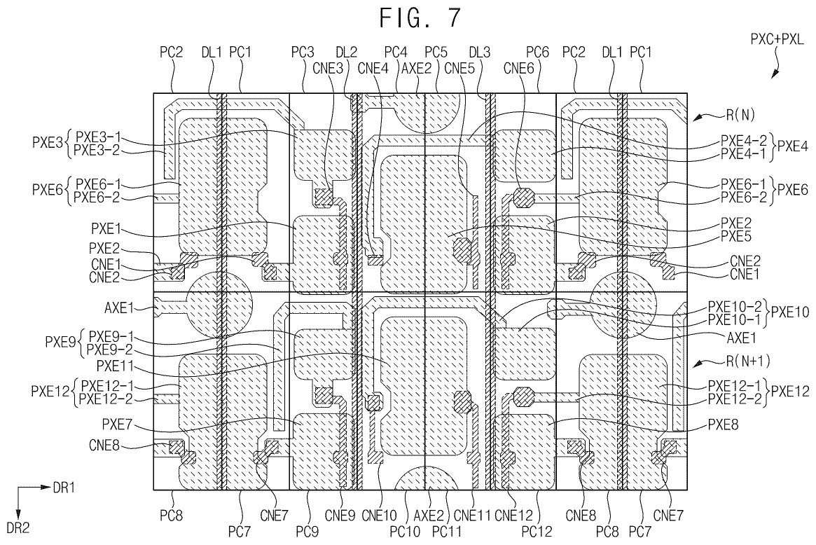

A number of transistors included in one pixel (e.g., the first pixel PX1 or the second pixel PX2) illustrated in FIGS. 3, 4, and 5 are illustrated in FIGS. 6-14, and a number of capacitors as illustrated as 2 are also illustrated in FIGS. 6-14, but the number of transistors and capacitors included in one pixel according to the present disclosure may not be necessarily limited thereto. For example, one pixel may include 5 or fewer to 7 or more transistors, or one pixel may include one capacitor or three or more capacitors.

Referring further to FIG. 2, circuit structure and operation method of the first pixel PX1 and the second pixel PX2 may be illustrated in FIGS. 3, 4, and 5, but the present disclosure may not be necessarily limited thereto, and circuit structure and operation method of the third pixel PX3 and the fourth pixel PX4 may be substantially the same as the circuit structure and the operation method of the first pixel PX1 and the second pixel PX2. In addition, circuit structure and operation method of the fifth pixel PX5 and the sixth pixel PX6 may be substantially the same as the circuit structure and the operation method of the first pixel PX1 and the second pixel PX2.

For example, the first pixel PX1 may be substantially the same as the third pixel PX3 and the fifth pixel PX5, and the second pixel PX2 may be substantially the same as the fourth pixel PX4 and the sixth pixel PX6. In addition, the third pixel PX3 and the fourth pixel PX4 may have a structure connected to the second data line DL2 and include light-emitting elements that emit light of the second color, and the fifth pixel PX5 and the sixth pixel PX6 may have a structure connected to the third data line DL3 and include light-emitting elements that emit light of the third color.

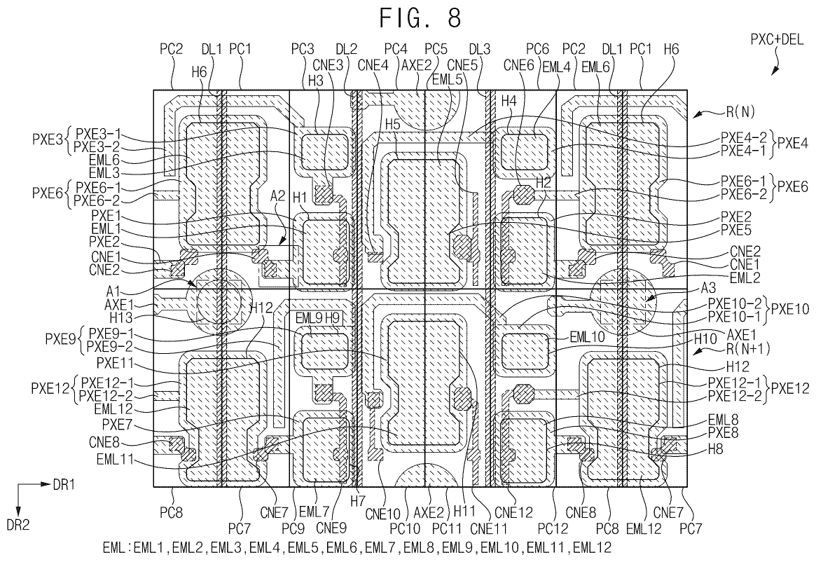

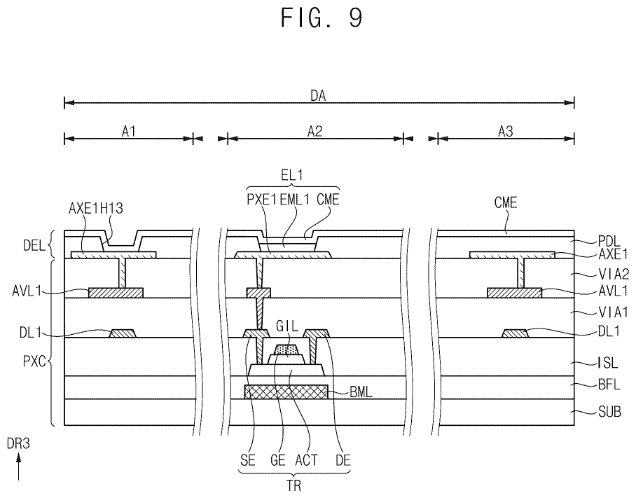

FIGS. 6, 7, and 8 are layout diagrams illustrating an example of an arrangement of components of the pixels included in the display panel of FIG. 1. FIG. 9 is a cross-sectional view illustrating each of A1, A2, and A3 areas of FIG. 8.

For example, FIGS. 6, 7, and 8 are layout diagrams for explaining an arrangement of each of a pixel circuit layer PXC and a light-emitting element layer DEL included in the display panel 100 in the display area DA.

Referring to FIGS. 6, 7, 8, and 9, the display panel 100 may include a pixel circuit layer PXC and a light-emitting element layer DEL. The pixel circuit layer PXC may include a substrate SUB, a bottom metal layer BML, a buffer layer BFL, an active layer ACT, a gate insulating layer GIL, a gate electrode GE, an insulating layer ISL, a source electrode SE, a drain electrode DE, a first via insulating layer VIA1, a first connection electrode CNE1, a second connection electrode CNE2, a third connection electrode CNE3, a fourth connection electrode CNE4, a fifth connection electrode CNE5, a sixth connection electrode CNE6, a seventh connection electrode CNE7, an eighth connection electrode CNE8, a ninth connection electrode CNE9, a tenth connection electrode CNE10, an eleventh connection electrode CNE11, a twelfth connection electrode CNE12, the first data line DL1, the second data line DL2, the third data line DL3, an auxiliary voltage line AVL1, and a second via insulating layer VIA2. The active layer ACT, the gate electrode GE, the source electrode SE, and the drain electrode DE may be form a transistor TR together. The transistor may be correspond to the 6-1th transistor T6-1.

The light-emitting element layer DEL may include a pixel electrode layer PXL, a pixel defining layer PDL, a light-emitting layer EML, and a common electrode CME. The pixel electrode layer PXL may include a first pixel electrode PXE1, a second pixel electrode PXE2, a third pixel electrode PXE3, a fourth pixel electrode PXE4, a fifth pixel electrode PXE5, a sixth pixel electrode PXE6, a seventh pixel electrode PXE7, an eighth pixel electrode PXE8, a ninth pixel electrode PXE9, a tenth pixel electrode PXE10, an eleventh pixel electrode PXE11, a twelfth pixel electrode PXE12, a first auxiliary electrode AXE1, and a second auxiliary electrode AXE2. The light-emitting layer EML may include a first light-emitting layer EML1, a second light-emitting layer EML2, a third light-emitting layer EML3, a fourth light-emitting layer EML4, a fifth light-emitting layer EML5, a sixth light-emitting layer EML6, a seventh light-emitting layer EML7, an eighth light-emitting layer EML8, a ninth light-emitting layer EML9, a tenth light-emitting layer EML10, an eleventh light-emitting layer EML11, and a twelfth light-emitting layer EML12.

The first pixel electrode PXE1, the first light-emitting layer EML1 and the common electrode CME may define a first light-emitting element EL1 together. However, in FIG. 9, the first pixel electrode PXE1, the first light-emitting layer EML1, and the common electrode CME are illustrated as defining the first light-emitting element EL1, instead of the first pixel electrode PXE1 and the first light-emitting layer EML1, a combination of one of a pixel electrode and a light-emitting layer from among the second pixel electrode PXE2 and the second light-emitting layer EML2, the third pixel electrode PXE3 and the third light-emitting layer EML3, the fourth pixel electrode PXE4 and the fourth light-emitting layer EML4, the fifth pixel electrode PXE5 and the fifth light-emitting layer EML5, the sixth pixel electrode PXE6 and the sixth light-emitting layer EML6, the seventh pixel electrode PXE7 and the seventh light-emitting layer EML7, the eighth pixel electrode PXE8 and the eighth light-emitting layer EML8, the ninth pixel electrode PXE9 and the ninth light-emitting layer EML9, the tenth pixel electrode PXE10 and the tenth light-emitting layer EML10, the eleventh pixel electrode PXE11 and the eleventh light-emitting layer EML11, and the twelfth pixel electrode PXE12 and the twelfth light-emitting layer EML12, and the common electrode CML may define a light-emitting element that emits light together.

Referring further to FIG. 6, the pixel circuit layer PXC may include a first pixel circuit PC1, a second pixel circuit PC2, a third pixel circuit PC3, a fourth pixel circuit PC4, a fifth pixel circuit PC5, a sixth pixel circuit PC6, a seventh pixel circuit PC7, an eighth pixel circuit PC8, a ninth pixel circuit PC9, a tenth pixel circuit PC10, an eleventh pixel circuit PC11, and a twelfth pixel circuit PC12.

The first pixel circuit PC1, the second pixel circuit PC2, the third pixel circuit PC3, the fourth pixel circuit PC4, the fifth pixel circuit PC5, and the sixth pixel circuit PC6 may be disposed in the Nth row R(N), and the seventh pixel circuit PC7, the eighth pixel circuit PC8, the ninth pixel circuit PC9, the tenth pixel circuit PC10, the eleventh pixel circuit PC11, and the twelfth pixel circuit PC12 may be disposed in the N+1th row R(N+1).

In one or more embodiments, the second pixel circuit PC2 adjacent to the first pixel circuit PC1 may be disposed in a direction opposite to the first direction DR1 of the first pixel circuit PC1 in a plan view. In one or more embodiments, the third pixel circuit PC3, the fourth pixel circuit PC4, the fifth pixel circuit PC5, and the sixth pixel circuit PC6 may be disposed between the first pixel circuit PC1 and the second pixel circuit PC2, which are not adjacent to each other and disposed in one row in a plan view.

In one or more embodiments, the eighth pixel circuit PC8 adjacent to the seventh pixel circuit PC7 may be disposed in a direction opposite to the first direction DR1 of the seventh pixel circuit PC7 in a plan view. In one or more embodiments, the ninth pixel circuit PC9, the tenth pixel circuit PC10, the eleventh pixel circuit PC11, and the twelfth pixel circuit PC12 may be disposed between the seventh pixel circuit PC7 and the eighth pixel circuit PC8, which are not adjacent to each other and disposed in one row in a plan view.

In one or more embodiments, pixel circuits disposed in one row may be disposed regularly along the first direction DR1. For example, pixel circuits disposed in the Nth row R(N) may be disposed in an order of the second pixel circuit PC2, the first pixel circuit PC1, the third pixel circuit PC3, the fourth pixel circuit PC4, the fifth pixel circuit PC5, and the sixth pixel circuit PC6. In addition, pixel circuits disposed in the N+1th row R(N+1) may be disposed in an order of the eighth pixel circuit PC8, the seventh pixel circuit PC7, the ninth pixel circuit PC9, the tenth pixel circuit PC10, the eleventh pixel circuit PC11, and the twelfth pixel circuit PC12.

In one or more embodiments, an arrangement of pixel circuits disposed in the Nth row R(N) and an arrangement of pixel circuits disposed in the N+1th row R(N+1) may be repeated along the second direction DR2. For example, the arrangement of pixel circuits disposed in the Nth row R(N) and the arrangement of pixel circuits disposed in the N+1th row R(N+1) may be alternately disposed along the second direction DR2.

In one or more embodiments, pixel circuits disposed in a same column along the second direction DR2 may be substantially the same. For example, each of the pixel circuits disposed in a same column along the second direction DR2 may be electrically connected to a light-emitting element that emits light of a same color, and may receive a same type of write gate signal (e.g., the first write gate signal GW1 or the second write gate signal GW2).

Specifically, each of the first pixel circuit PC1 and the seventh pixel circuit PC7 may be electrically connected to a light-emitting element that emits light of a first color and may receive a first write gate signal GW1. Each of the second pixel circuit PC2 and the eighth pixel circuit PC8 may be electrically connected to a light-emitting element that emits light of the first color and may receive a second write gate signal GW2. Each of the third pixel circuit PC3 and the ninth pixel circuit PC9 may be each electrically connected to a light-emitting element that emits light of a second color and may receive a first write gate signal GW1. Each of the fourth pixel circuit PC4 and the tenth pixel circuit PC10 may be each electrically connected to a light-emitting element that emits light of the second color and may receive a second write gate signal GW2. Each of the fifth pixel circuit PC5 and the eleventh pixel circuit PC11 is electrically connected to a light-emitting element that emits light of a third color and may receive a first write gate signal GW1. Each of the sixth pixel circuit PC6 and the twelfth pixel circuit PC12 may be electrically connected to a light-emitting element that emits light of the third color and may receive a second write gate signal GW2.

The first pixel circuit PC1 may be a portion of the first pixel PX1 including transistors (e.g., the 1-1th transistor T1-1, the 2-1th transistor T2-1, the 3-1th transistor T3-1, the 4-1th transistor T4-1, the 5-1th transistor T5-1, and the 6-1th transistor T6-1) for operation and control of a light-emitting element (e.g., the first light-emitting element EL1) included in the first pixel PX1.

The second pixel circuit PC2 may be a portion of the second pixel PX2 including transistors (e.g., the 1-2th transistor T1-2, the 2-2th transistor T2-2, the 3-2th transistor T3-2, the 4-2th transistor T4-2, the 5-2th transistor T5-2, and the 6-2th transistor T6-2) for operation and control of a light-emitting element (e.g., the second light-emitting element EL2) included in the second pixel PX2.

The third pixel circuit PC3 may be a portion of the third pixel PX3 including transistors for operation and control of a light-emitting element included in the third pixel PX3. The fourth pixel circuit PC4 may be a portion of the fourth pixel PX4 including transistors for operation and control of a light-emitting element included in the fourth pixel PX4. The fifth pixel circuit PC5 may be a portion of the fifth pixel PX5 including transistors for operation and control of a light-emitting element included in the fifth pixel PX5. The sixth pixel circuit PC6 may be a portion of the sixth pixel PX6 including transistors for operation and control of a light-emitting element included in the sixth pixel PX6.

In the present disclosure, the light-emitting element included in the third pixel PX3 may be referred to as a third light-emitting element, the light-emitting element included in the fourth pixel PX4 may be referred to as a fourth light-emitting element, the light-emitting element included in the fifth pixel PX5 may be referred to as a fifth light-emitting element, and the light-emitting element included in the sixth pixel PX6 may be referred to as a sixth light-emitting element.

The seventh pixel circuit PC7 may be substantially the same as the first pixel circuit PC1, the eighth pixel circuit PC8 may be substantially the same as the second pixel circuit PC2, the ninth pixel circuit PC9 may be substantially the same as the third pixel circuit PC3, the tenth pixel circuit PC10 may be substantially the same as the fourth pixel circuit PC4, the eleventh pixel circuit PC11 may be substantially the same as the fifth pixel circuit PC5, and the twelfth pixel circuit PC12 may be substantially the same as the sixth pixel circuit PC6.

Specifically, the seventh pixel circuit PC7, the ninth pixel circuit PC9, and the eleventh pixel circuit PC11 may be pixels included in the first pixel group PXG1, like the first pixel circuit PC1, the third pixel circuit PC3, and the fifth pixel circuit PC5. In addition, the eighth pixel circuit PC8, the tenth pixel circuit PC10, and the twelfth pixel circuit PC12 may be pixels included in the second pixel group PXG2, such as the second pixel circuit PC2, the fourth pixel circuit PC4, and the sixth pixel circuit PC6.

In an A2 area of FIG. 9, a cross-section of a portion of the first pixel circuit PC1 is illustrated, and each of the second pixel circuit PC2, the third pixel circuit PC3, the fourth pixel circuit PC4, the fifth pixel circuit PC5, the sixth pixel circuit PC6, the seventh pixel circuit PC7, the eighth pixel circuit PC8, the ninth pixel circuit PC9, the tenth pixel circuit PC10, the eleventh pixel circuit PC11, and the twelfth pixel circuit PC12 according to the present disclosure may have a cross-sectional structure substantially the same as the cross-section of the first pixel circuit PC1.

The substrate SUB may be a base of the display panel 100. The substrate SUB may include a transparent material or an opaque material. The substrate SUB may be a transparent resin substrate such as a polyimide (PI). For example, the substrate SUB including a polyimide may include a first organic layer, a first barrier layer, a second organic layer, and/or the like. For another example, the substrate SUB may include a quartz substrate (e.g., a synthetic quartz substrate), a calcium fluoride substrate, a non-alkali glass substrate, and/or the like. These may be used alone or in combination with each other.

The bottom metal layer BML may be disposed on the substrate SUB. The bottom metal layer BML may prevent diffusion of impurities into the active layer ACT or prevent static electricity generated in the transistor (TR). In one or more embodiments, the bottom metal layer BML may include a conductive material. For example, the conductive material may include molybdenum (Mo), copper (Cu), aluminum (Al), titanium (Ti), and/or the like. These may be used alone or in combination with each other.

The buffer layer BFL may be disposed on the bottom metal layer BML and the substrate SUB. The buffer layer BFL may block diffusion of impurities such as oxygen, moisture, and/or the like, into the upper portion of the substrate SUB through the substrate SUB. The buffer layer BFL may provide a flat upper surface on the upper portion of the substrate SUB. The buffer layer BFL may include an inorganic insulating material.

The active layer ACT may be disposed on the buffer layer BFL. The active layer ACT may include a source area, a drain area, and a channel area disposed between the source area and the drain area.

In one or more embodiments, the active layer ACT may include an oxide semiconductor. For example, the oxide semiconductor may include indium (In), gallium (Ga), tin (Sn), zirconium (Zr), vanadium (V), hafnium (Hf), cadmium (Cd), germanium GE, chromium, titanium, zinc (Zn), and/or the like. These may be used alone or in combination with each other. However, the materials included in the active layer ACT according to the present disclosure may not be necessarily limited thereto, and the active layer ACT may include an organic semiconductor and/or a silicon semiconductor, and/or the like. For example, the silicon semiconductor may be polycrystalline silicon, amorphous silicon, and/or the like.

The gate insulating layer GIL may be disposed on the active layer ACT. In one or more embodiments, the gate insulating layer GIL may include an inorganic insulating material. The inorganic insulating material may include silicon oxide (SiOₓ), silicon nitride (SiNₓ), silicon oxynitride (SiOₓN_{y}), and/or the like. These may be used alone or in combination with each other.

The gate electrode GE may be disposed on the gate insulating layer GIL. The gate electrode GE may overlap the channel area of the active layer ACT in a plan view. In one or more embodiments, the gate electrode GE may include a conductive material.

The first write gate line GWL1 and the second write line GWL2 may be disposed in the pixel circuit layer PXC. In one or more embodiments, each of the first write gate line GWL1 and the second write gate line GWL2 may be disposed in (or at) a same layer as the gate electrode GE. For example, the first write gate line GWL1, the second write gate line GWL2, and the gate electrode GE may include a same material and may be formed through a same process. However, an interlayer arrangement of the first write gate line GWL1, the second write gate line GWL2, and the gate electrode GE according to the present disclosure may not be necessarily limited thereto.

The insulating layer ISL may be disposed on the buffer layer BFL. For example, the insulating layer ISL may cover the gate electrode GE on the buffer layer BFL. In one or more embodiments, the insulating layer ISL may include an inorganic insulating material and/or an organic insulating material. In one or more embodiments, the insulating layer ISL may have a substantially flat upper surface. However, the insulating layer ISL according to the present disclosure may not be necessarily limited thereto, and the insulating layer ISL may have a substantially uniform thickness along the profile of the gate electrode GE.

The source electrode SE and the drain electrode DE may be disposed on the insulating layer ISL. The source electrode SE and the drain electrode DE may contact the active layer ACT through a contact hole penetrating the insulating layer ISL in the thickness direction (e.g., the third direction DR3). For example, the source electrode SE may contact the source area of the active layer ACT, and the drain electrode DE may contact the drain area of the active layer ACT. In one or more embodiments, each of the source electrode SE and the drain electrode DE may include a conductive material.

The first data line DL1, the second data line DL2, and the third data line DL3 may be disposed on the insulating layer ISL. In one or more embodiments, each of the first data line DL1, the second data line DL2, and the third data line DL3 may include a conductive material. In one or more embodiments, the first data line DL1, the second data line DL2, and the third data line DL3 may be disposed in (or at) a same layer as each other. For example, the first data line DL1, the second data line DL2, and the third data line DL3 may include a same material and may be formed through a same process.

In one or more embodiments, the first data line DL1, the second data line DL2, and the third data line DL3 may be disposed in (or at) a same layer as the source electrode SE and the drain electrode DE. For example, the first data line DL1, the second data line DL2, and the third data line DL3 may include a same material as the source electrode SE and the drain electrode DE, and may be formed through a same process. However, an arrangement of each of the first data line DL1, the second data line DL2, and the third data line DL3 according to the present disclosure may not be necessarily limited thereto, and the first data line DL1, the second data line DL2, and the third data line DL3 may be disposed in a different layer from the source electrode SE and the drain electrode DE.

In one or more embodiments, the first data line DL1 may be disposed between the first pixel circuit PC1 and the second pixel circuit PC2 that are adjacent to each other in a plan view. In one or more embodiments, the second data line DL2 may be disposed between the third pixel circuit PC3 and the fourth pixel circuit PC4 that are adjacent to each other in a plan view. In one or more embodiments, the third data line DL3 may be disposed between the fifth pixel circuit PC5 and the sixth pixel circuit PC6 that are adjacent to each other in a plan view.

In one or more embodiments, each of the first data line DL1, the second data line DL2, and the third data line DL3 may extend within the pixel circuit layer PXC along the second direction DR2. Specifically, the first data line DL1, the second data line DL2, and the third data line DL3 may cross both the Nth row R(N) and the N+1th row R(N+1).

The first via insulating layer VIA1 may be disposed on the insulating layer ISL. In one or more embodiments, the first via insulating layer VIA1 may have a substantially flat upper surface. In one or more embodiments, the first via insulating layer VIA1 may include an organic material such as polyimide.

The first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12 may be disposed on the first via insulating layer VIA1. For example, the first connection electrode CNE1, the second connection electrode CNE2, the third connection electrode CNE3, the fourth connection electrode CNE4, the fifth connection electrode CNE5, and the sixth connection electrode CNE6 may be disposed in the Nth row R(N) in a plan view. In addition, the seventh connection electrode CNE7, the eighth connection electrode CNE8, the ninth connection electrode CNE9, the tenth connection electrode CNE10, the eleventh connection electrode CNE11, and the twelfth connection electrode CNE12 may be disposed in the N+1th row R(N+1) in a plan view.

In one or more embodiments, the first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12 may be disposed on the first data line DL1, the second data line DL2, and the third data line DL3.

However, an arrangement relationship between the first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12 and the first data line DL1, the second data line DL2, and the third data line DL3 according to the present disclosure may not be necessarily limited thereto. For example, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12 and the first data line DL1, the second data line DL2, and the third data line DL3 may be disposed in (or at) a same layer.

The first connection electrode CNE1 may be included in the first pixel circuit PC1. The first connection electrode CNE1 may be electrically connected to a light-emitting control transistor (e.g., the 6-1th transistor T6-1) included in the first pixel circuit PC1. For example, the first connection electrode CNE1 may contact the source electrode SE of the transistor TR through a contact hole penetrating the first via insulating layer VIA1 in the thickness direction (e.g., the third direction DR3). However, the first connection electrode CNE1 according to the present disclosure may not be necessarily limited thereto, and the first connection electrode CNE1 may contact the drain electrode DE of the transistor TR through a contact hole penetrating the first via insulating layer VIA1 in the thickness direction (e.g., the third direction DR3).

In one or more embodiments, the first connection electrode CNE1 may be repeatedly disposed along the second direction DR2 in units of two rows. For example, when the first connection electrode CNE1 is disposed in an area where the first pixel circuit PC1 is disposed in the Nth row, the first connection electrode CNE1 may be disposed in an area where each of the first pixel circuits PC1 is disposed in rows such as the N+2th row, a N+4th row, and/or the like.

The second connection electrode CNE2 may be included in the second pixel circuit PC2. The second connection electrode CNE2 may be electrically connected to a light-emitting control transistor (e.g., the 6-2 transistor T6-2) included in the second pixel circuit PC2. For example, the second connection electrode CNE2 may contact a source electrode of the light-emitting control transistor included in the second pixel circuit PC2 through a contact hole penetrating the first via insulating layer VIA1 in the thickness direction (e.g., the third direction DR3). However, the second connection electrode CNE2 according to the present disclosure may not be necessarily limited thereto, and the second connection electrode CNE2 may also contact a drain electrode of the light-emitting control transistor included in the second pixel circuit PC2 through a contact hole penetrating the first via insulating layer VIA1 in the thickness direction (e.g., the third direction DR3).

In one or more embodiments, the second connection electrode CNE2 may be spaced (e.g., spaced apart) from the first connection electrode CNE1 in a plan view. In one or more embodiments, the second connection electrode CNE2 may be disposed in the opposite direction of the first direction DR1 from the first connection electrode CNE1 adjacent to the second connection electrode CNE2. In one or more embodiments, the first connection electrode CNE1 and the second connection electrode CNE2 may be symmetrical to each other based on the first data line DL1 in a plan view. However, the first connection electrode CNE1 and the second connection electrode CNE2 according to the present disclosure may not be necessarily limited thereto.

In one or more embodiments, the second connection electrode CNE2 may be repeatedly disposed along the second direction DR2 in units of two rows. For example, when the second connection electrode CNE2 is disposed in an area where the second pixel circuit PC2 is disposed in the Nth row, the second connection electrode CNE2 may be disposed in an area where each of the second pixel circuits PC2 is disposed in rows such as the N+2th row and the N+4th row.

The third connection electrode CNE3 may be included in the third pixel circuit PC3. The third connection electrode CNE3 may be electrically connected to the light-emitting control transistor (e.g., the 6-1th transistor T6-1) included in the third pixel circuit PC3. For example, the third connection electrode CNE3 may contact the source electrode of the light-emitting control transistor included in the third pixel circuit PC3 through a contact hole penetrating the first via insulating layer VIA1 in the thickness direction (e.g., the third direction DR3). However, the third connection electrode CNE3 according to the present disclosure may not be necessarily limited thereto, and the third connection electrode CNE3 may also contact the drain electrode of the light-emitting control transistor included in the third pixel circuit PC3 through a contact hole penetrating the first via insulating layer VIA1 in the thickness direction (e.g., the third direction DR3).

In one or more embodiments, the third connection electrode CNE3 may be spaced (e.g., spaced apart) from the first connection electrode CNE1 in a plan view. In one or more embodiments, the third connection electrode CNE3 may be disposed in the first direction DR1 from the first connection electrode CNE1 adjacent to the third connection electrode CNE3.

In one or more embodiments, the third connection electrode CNE3 may be repeatedly disposed along the second direction DR2 in units of two rows. For example, when the third connection electrode CNE3 is disposed in an area where the third pixel circuit PC3 is disposed in the Nth row, the third connection electrode CNE3 may be disposed in an area where each of the third pixel circuits PC3 is disposed in rows such as the N+2th row, the N+4th row, and/or the like.

The fourth connection electrode CNE4 may be included in the fourth pixel circuit PC4. The fourth connection electrode CNE4 may be electrically connected to the light-emitting control transistor (e.g., the 6-1th transistor T6-1) included in the fourth pixel circuit PC4. For example, the fourth connection electrode CNE4 may contact the source electrode of the light-emitting control transistor included in the fourth pixel circuit PC4 through a contact hole penetrating the first via insulating layer VIA1 in the thickness direction (e.g., the third direction DR3). However, the fourth connection electrode CNE4 according to the present disclosure may not be necessarily limited thereto, and the fourth connection electrode CNE4 may also contact the drain electrode of the light-emitting control transistor included in the fourth pixel circuit PC4 through a contact hole penetrating the first via insulating layer VIA1 in the thickness direction (e.g., the third direction DR3).

In one or more embodiments, the fourth connection electrode CNE4 may be spaced (e.g., spaced apart) from the third connection electrode CNE3 in a plan view. In one or more embodiments, the second data line DL2 may be disposed between the third connection electrode CNE3 and the fourth connection electrode CNE4 in a plan view.

In one or more embodiments, the fourth connection electrode CNE4 may be repeatedly disposed along the second direction DR2 in units of two rows. For example, when the fourth connection electrode CNE4 is disposed in an area where the fourth pixel circuit PC4 is disposed in the Nth row, the fourth connection electrode CNE4 may be disposed in an area where each of the fourth pixel circuits PC4 is disposed in the N+2th row, the N+4th row, and/or the like.

The fifth connection electrode CNE5 may be included in the fifth pixel circuit PC5. The fifth connection electrode CNE5 may be electrically connected to the light-emitting control transistor (e.g., the 6-1th transistor T6-1) included in the fifth pixel circuit PC5. For example, the fifth connection electrode CNE5 may contact the source electrode of the light-emitting control transistor included in the fifth pixel circuit PC5 through a contact hole penetrating the first via insulating layer VIA1 in the thickness direction (e.g., the third direction DR3). However, the fifth connection electrode CNE5 according to the present disclosure may not be necessarily limited thereto, and the fifth connection electrode CNE5 may contact the drain electrode of the light-emitting control transistor included in the fifth pixel circuit PC5 through a contact hole penetrating the first via insulating layer VIA1 in the thickness direction (e.g., the third direction DR3).

In one or more embodiments, the fifth connection electrode CNE5 may be spaced (e.g., spaced apart) from the fourth connection electrode CNE4 in a plan view. In one or more embodiments, the fifth connection electrode CNE5 may be located in the first direction DR1 from the fourth connection electrode CNE4 adjacent to the fifth connection electrode CNE5.

In one or more embodiments, The fifth connection electrode CNE5 may be repeatedly disposed along the second direction DR2 in units of two rows. For example, when the fifth connection electrode CNE5 is disposed in an area where the fifth pixel circuit PC5 is disposed in the Nth row, the fifth connection electrode CNE5 may be disposed in an area where each of the fifth pixel circuits PC5 is disposed in the N+2th row, the N+4th row, and/or the like.

The sixth connection electrode CNE6 may be included in the sixth pixel circuit PC6. The sixth connection electrode CNE6 may be electrically connected to the light-emitting control transistor (e.g., the 6-1th transistor T6-1) included in the sixth pixel circuit PC6. For example, the sixth connection electrode CNE6 may contact the source electrode of the light-emitting control transistor included in the sixth pixel circuit PC6 through a contact hole penetrating the first via insulating layer VIA1 in the thickness direction (e.g., the third direction DR3). However, the sixth connection electrode CNE6 according to the present disclosure may not be necessarily limited thereto, and the sixth connection electrode CNE6 may contact the drain electrode of the light-emitting control transistor included in the sixth pixel circuit PC6 through a contact hole penetrating the first via insulating layer VIA1 in the thickness direction (e.g., the third direction DR3).

In one or more embodiments, the sixth connection electrode CNE6 may be spaced (e.g., spaced apart) from the fifth connection electrode CNE5 in a plan view. In one or more embodiments, the third data line DL3 may be disposed between the fifth connection electrode CNE5 and the sixth connection electrode CNE6 in a plan view.

In one or more embodiments, the sixth connection electrode CNE6 may be repeatedly disposed along the second direction DR2 in units of two rows. For example, when the sixth connection electrode CNE6 is placed in an area where the sixth pixel circuit PC6 is placed in the Nth row, the sixth connection electrode CNE6 may be placed in an area where each of the sixth pixel circuits PC6 is placed in the N+2th row, the N+4th row, and the like.

The seventh connection electrode CNE7 may be included in the seventh pixel circuit PC7. The seventh connection electrode CNE7 may be electrically connected to the light-emitting control transistor (e.g., the 6-1th transistor T6-1) included in the seventh pixel circuit PC7. For example, the seventh connection electrode CNE7 may contact the source electrode SE of the light-emitting control transistor included in the seventh pixel circuit PC7 through a contact hole penetrating the first via insulating layer VIA1 in the thickness direction (e.g., the third direction DR3). However, the seventh connection electrode CNE7 according to the present disclosure may not be necessarily limited thereto, and the seventh connection electrode CNE7 may also contact the drain electrode of the light-emitting control transistor included in the seventh pixel circuit PC7 through a contact hole penetrating the first via insulating layer VIA1 in the thickness direction (e.g., the third direction DR3).

The seventh connection electrode CNE7 may be spaced (e.g., spaced apart) from the first connection electrode CNE1 in the second direction DR2 in a plan view. In a plan view, the seventh connection electrode CNE7 may adjoin to each of the first pixel circuit PC1 and the seventh pixel circuit PC7 and may be symmetrical with the first connection electrode CNE1 based on an virtual line parallel to the first direction DR1.

In one or more embodiments, the seventh connection electrode CNE7 may be repeatedly disposed along the second direction DR2 in units of two rows. For example, when the seventh connection electrode CNE7 is disposed in an area where the seventh pixel circuit PC7 is disposed in the N+1-th row, the seventh connection electrode CNE7 may be disposed in an area where each of the seventh pixel circuits PC7 is disposed in a N+3-th row, a N+5-th row, and/or the like. In one or more embodiments, the first connection electrode CNE1 and the seventh connection electrode CNE7 may be alternately disposed along the second direction DR2 in a plan view.

The eighth connection electrode CNE8 may be included in the eighth pixel circuit PC8. The eighth connection electrode CNE8 may be electrically connected to the light-emitting control transistor (e.g., the 6-1th transistor T6-1) included in the eighth pixel circuit PC8. For example, the eighth connection electrode CNE8 may contact the source electrode SE of the light-emitting control transistor included in the eighth pixel circuit PC8 through a contact hole penetrating the first via insulating layer VIA1 in the thickness direction (e.g., the third direction DR3). However, the eighth connection electrode CNE8 according to the present disclosure may not be necessarily limited thereto, and the eighth connection electrode CNE8 may also contact the drain electrode of the light-emitting control transistor included in the eighth pixel circuit PC8 through a contact hole penetrating the first via insulating layer VIA1 in the thickness direction (e.g., the third direction DR3).

The eighth connection electrode CNE8 may be spaced (e.g., spaced apart) from the second connection electrode CNE2 in the second direction DR2 in a plan view. In a plan view, the eighth connection electrode CNE8 may contact each of the second pixel circuit PC2 and the eighth pixel circuit PC8 and may be symmetrical with the second connection electrode CNE2 based on an virtual line parallel to the first direction DR1.

In one or more embodiments, the eighth connection electrode CNE8 may be repeatedly disposed along the second direction DR2 in units of two rows. For example, when the eighth connection electrode CNE8 is disposed in an area where the eighth pixel circuit PC8 is disposed in the N+1-th row, the eighth connection electrode CNE8 may be disposed in an area where each of the eighth pixel circuits PC8 is disposed in the N+3-th row, the N+5-th row, and/or the like. In one or more embodiments, the second connection electrode CNE2 and the eighth connection electrode CNE8 may be alternately disposed along the second direction DR2 in a plan view.

The ninth connection electrode CNE9 may be included in the ninth pixel circuit PC9. The ninth connection electrode CNE9 may be electrically connected to the light-emitting control transistor (e.g., the 6-1th transistor T6-1) included in the ninth pixel circuit PC9. For example, the ninth connection electrode CNE9 may contact the source electrode SE of the light-emitting control transistor included in the ninth pixel circuit PC9 through a contact hole penetrating the first via insulating layer VIA1 in the thickness direction (e.g., the third direction DR3). However, the ninth connection electrode CNE9 according to the present disclosure may not be necessarily limited thereto, and the ninth connection electrode CNE9 may also contact the drain electrode of the light-emitting control transistor included in the ninth pixel circuit PC9 through a contact hole penetrating the first via insulating layer VIA1 in the thickness direction (e.g., the third direction DR3).

The ninth connection electrode CNE9 may be spaced (e.g., spaced apart) from the third connection electrode CNE3 in the second direction DR2 in a plan view. In a plan view, a shape of the ninth connection electrode CNE9 and a shape of the third connection electrode CNE3 may be substantially a same. However, a shape of each of the third connection electrode CNE3 and the ninth connection electrode CNE9 in a plan view according to the present disclosure may not be necessarily limited thereto.

In one or more embodiments, the ninth connection electrode CNE9 may be repeatedly disposed along the second direction DR2 in units of two rows. For example, when the ninth connection electrode CNE9 is disposed in an area where the ninth pixel circuit PC9 is disposed in the N+1-th row, the ninth connection electrode CNE9 may be disposed in an area where each of the ninth pixel circuits is disposed in rows such as the N+3-th row, the N+5-th row, and/or the like.

The tenth connection electrode CNE10 may be included in the tenth pixel circuit PC10. The tenth connection electrode CNE10 may be electrically connected to the light-emitting control transistor (e.g., the 6-1th transistor T6-1) included in the tenth pixel circuit PC10. For example, the tenth connection electrode CNE10 may contact the source electrode SE of the light-emitting control transistor included in the tenth pixel circuit PC10 through a contact hole penetrating the first via insulating layer VIA1 in the thickness direction (e.g., the third direction DR3). However, the tenth connection electrode CNE10 according to the present disclosure may not be necessarily limited thereto, and the tenth connection electrode CNE10 may also contact the drain electrode of the light-emitting control transistor included in the tenth pixel circuit PC10 through a contact hole penetrating the first via insulating layer VIA1 in the thickness direction (e.g., the third direction DR3).

The tenth connection electrode CNE10 may be spaced (e.g., spaced apart) from the fourth connection electrode CNE4 in the second direction DR2 in a plan view. In a plan view, a shape of the tenth connection electrode CNE10 and a shape of the fourth connection electrode CNE4 may be different. For example, in a plan view, a size of the tenth connection electrode CNE10 may be larger than a size of the fourth connection electrode CNE4. However, a shape of each of the fourth connection electrode CNE4 and the tenth connection electrode CNE10 in a plan view according to the present disclosure may not be necessarily limited thereto.

In one or more embodiments, the tenth connection electrode CNE10 may be repeatedly disposed along the second direction DR2 in units of two rows. For example, when the tenth connection electrode CNE10 is disposed in an area where the tenth pixel circuit PC10 is disposed in the N+1th row, the tenth connection electrode CNE10 may be disposed in an area where each of the tenth pixel circuits is disposed in rows such as the N+3th row and the N+5th row. In one or more embodiments, the fourth connection electrode CNE4 and the tenth connection electrode CNE10 may be disposed alternately along the second direction DR2 in a plan view.

The eleventh connection electrode CNE11 may be included in the eleventh pixel circuit PC11. The eleventh connection electrode CNE11 may be electrically connected to the light-emitting control transistor (e.g., the 6-1th transistor T6-1) included in the eleventh pixel circuit PC11. For example, the eleventh connection electrode CNE11 may contact the source electrode SE of the light-emitting control transistor included in the eleventh pixel circuit PC11 through a contact hole penetrating the first via insulating layer VIA1 in the thickness direction (e.g., the third direction DR3). However, the eleventh connection electrode CNE11 according to the present disclosure may not be necessarily limited thereto, and the eleventh connection electrode CNE11 may contact the drain electrode of the light-emitting control transistor included in the eleventh pixel circuit PC11 through a contact hole penetrating the first via insulating layer VIA1 in the thickness direction (e.g., the third direction DR3).

The eleventh connection electrode CNE11 may be spaced (e.g., spaced apart) from the fifth connection electrode CNE5 in the second direction DR2 in a plan view. In a plan view, a shape of the eleventh connection electrode CNE11 and a shape of the fifth connection electrode CNE5 may be different. However, a shape of each of the fifth connection electrode CNE5 and the eleventh connection electrode CNE11 in a plan view according to the present disclosure may not be necessarily limited thereto.

In one or more embodiments, the eleventh connection electrode CNE11 may be repeatedly disposed along the second direction DR2 in units of two rows. For example, if the eleventh connection electrode CNE11 is disposed in an area where the eleventh pixel circuit PC11 is disposed in the N+1th row, the eleventh connection electrode CNE11 may be disposed in an area where each of the eleventh pixel circuits is disposed in the N+3th row, the N+5th row, and/or the like. In one or more embodiments, the fifth connection electrode CNE5 and the eleventh connection electrode CNE11 may be disposed alternately along the second direction DR2 in a plan view.

The twelfth connection electrode CNE12 may be included in the twelfth pixel circuit PC12. The twelfth connection electrode CNE12 may be electrically connected to the light-emitting control transistor included in the twelfth pixel circuit PC12. For example, the twelfth connection electrode CNE12 may contact the source electrode SE of the light-emitting control transistor included in the twelfth pixel circuit PC12 through a contact hole penetrating the first via insulating layer VIA1 in the thickness direction (e.g., the third direction DR3). However, the twelfth connection electrode CNE12 according to embodiments of the present disclosure may not be necessarily limited thereto, and the twelfth connection electrode CNE12 may also contact the drain electrode of the light-emitting control transistor included in the twelfth pixel circuit PC12 through a contact hole penetrating the first via insulating layer VIA1 in the thickness direction (e.g., the third direction DR3).

The twelfth connection electrode CNE12 may be spaced (e.g., spaced apart) from the sixth connection electrode CNE6 in the second direction DR2 in a plan view. In a plan view, a shape of the twelfth connection electrode CNE12 and a shape of the sixth connection electrode CNE6 may be substantially a same. However, a shape of each of the sixth connection electrode CNE6 and the twelfth connection electrode CNE12 in a plan view according to the present disclosure may not be necessarily limited thereto.

In one or more embodiments, the twelfth connection electrode CNE12 may be repeatedly disposed along the second direction DR2 in units of two rows. For example, when the twelfth connection electrode CNE12 is disposed in an area where the twelfth pixel circuit PC12 is disposed in the N+1-th row, the twelfth connection electrode CNE12 may be disposed in an area where each of the twelfth pixel circuits is disposed in rows such as the N+3-th row, the N+5-th row, and/or the like.

In one or more embodiments, connection electrodes disposed in one row may be regularly disposed along the first direction DR1. For example, the connection electrodes disposed in the Nth row R(N) may be disposed in the order of the second connection electrode CNE2, the first connection electrode CNE1, the third connection electrode CNE3, the fourth connection electrode CNE4, the fifth connection electrode CNE5, and the sixth connection electrode CNE6. In addition, the connection electrodes disposed in the N+1th row R(N+1) may be disposed in an order of the eighth connection electrode CNE8, the seventh connection electrode CNE7, the ninth connection electrode CNE9, the tenth connection electrode CNE10, the eleventh connection electrode CNE11, and the twelfth connection electrode CNE12.

In one or more embodiments, an arrangement of the connection electrodes disposed in the Nth row R(N) and an arrangement of the connection electrodes disposed in the N+1th row R(N+1) may be repeated along the second direction DR2. For example, the arrangement of the connection electrodes disposed in the Nth row R(N) and the arrangement of the connection electrodes disposed in the N+1th row R(N+1) may be disposed alternately along the second direction DR2.

However, arrangement, shape, size, and/or the like, of the first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12 according to the present disclosure may be shown as examples and may not be necessarily limited thereto.

The first auxiliary voltage line AVL1 may be disposed on the first via insulating layer VIA1. In one or more embodiments, the first auxiliary voltage line AVL1 may be disposed in (e.g., at) a same layer as the first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12. However, an arrangement of the first auxiliary voltage line AVL1 according to the present disclosure may not be necessarily limited thereto.

In one or more embodiments, the first auxiliary voltage line AVL1 may be electrically connected to the first auxiliary electrode AXE1 to prevent a voltage drop phenomenon of the second power voltage ELVSS. In one or more embodiments, the first auxiliary voltage line AVL1 may be spaced (e.g., spaced apart) from the light-emitting layer EML in a plan view.

The second via insulating layer VIA2 may be disposed on the first via insulating layer VIA1. In one or more embodiments, the second via insulating layer VIA2 may include substantially a same material as the first via insulating layer VIA1. For example, the second via insulating layer VIA2 may include an organic insulating material.

The pixel electrode layer PXL may be disposed on the second via insulating layer VIA2. In one or more embodiments, the first pixel electrode PXE1, the second pixel electrode PXE2, the third pixel electrode PXE3, the fourth pixel electrode PXE4, the fifth pixel electrode PXE5, the sixth pixel electrode PXE6, the seventh pixel electrode PXE7, the eighth pixel electrode PXE8, the ninth pixel electrode PXE9, the tenth pixel electrode PXE10, the eleventh pixel electrode PXE11, the twelfth pixel electrode PXE12, the first auxiliary electrode AXE1 and the second auxiliary electrode AXE2 may be spaced (e.g., spaced apart) from each other in a plan view.

The first pixel electrode PXE1 may be electrically connected to the first pixel circuit PC1. For example, the first pixel electrode PXE1 may be electrically connected to the first pixel circuit PC1 through the first connection electrode CNE1. Specifically, the first pixel electrode PXE1 may contact the first connection electrode CNE1 through a contact hole penetrating the second via insulating layer VIA2 in the thickness direction (e.g., in the third direction DR3).

In one or more embodiments, the first pixel electrode PXE1 may overlap the first pixel circuit PC1 in a plan view. In one or more embodiments, the first pixel electrode PXE1 may overlap the third pixel circuit PC3 in a plan view. Specifically, the first portion of the first pixel electrode PXE1 may overlap the third pixel circuit PC3 in a plan view, and the second portion protruding from the first portion of the first pixel electrode PXE1 in the opposite direction to the first direction DR1 may overlap the first pixel circuit PC1 in a plan view. In addition, the first portion of the first pixel electrode PXE1 may overlap a portion of the third connection electrode CNE3 in a plan view.

The second pixel electrode PXE2 may be electrically connected to the second pixel circuit PC2. For example, the second pixel electrode PXE2 may be electrically connected to the second pixel circuit PC2 through the second connection electrode CNE2. Specifically, the second pixel electrode PXE2 may contact the second connection electrode CNE2 through a contact hole penetrating the second via insulating layer VIA2 in the thickness direction (e.g., in the third direction DR3).

In one or more embodiments, the second pixel electrode PXE2 may overlap the second pixel circuit PC2 in a plan view. In one or more embodiments, the second pixel electrode PXE2 may overlap the sixth pixel circuit PC6 in a plan view. Specifically, a first portion of the second pixel electrode PXE2 overlaps the sixth pixel circuit PC6 in a plan view, and a second portion of the second pixel electrode PXE2 protruding in the first direction DR1 from the first portion may overlap the second pixel circuit PC2 in a plan view. In addition, the first portion of the second pixel electrode PXE2 may overlap a portion of the sixth connection electrode CNE6 in a plan view.

In one or more embodiments, the second pixel electrode PXE2 disposed in the first direction DR1 from the first pixel electrode PXE1 in a plan view may contact the fourth pixel circuit PC4 and the fifth pixel circuit PC5 in a plan view, and may be symmetrical with the first pixel electrode PXE1 based on an virtual line parallel to the second direction DR2. In one or more embodiments, the second pixel electrode PXE2 disposed in the opposite direction of the first direction DR1 from the first pixel electrode PXE1 in a plan view may be symmetrical with the first pixel electrode PXE1 based on the first data line DL1.

The third pixel electrode PXE3 may be electrically connected to the third pixel circuit PC3. For example, the third pixel electrode PXE3 may be electrically connected to the third pixel circuit PC3 through the third connection electrode CNE3. Specifically, the third pixel electrode PXE3 may contact the third connection electrode CNE3 through a contact hole penetrating the second via insulating layer VIA2 in the thickness direction (e.g., in the third direction DR3).

The third pixel electrode PXE3 may include a first main portion PXE3-1 and a first extending portion PXE3-2. The first main portion PXE3-1 and the first extending portion PXE3-2 may be formed integrally. In one or more embodiments, the first extending portion PXE3-2 may protrude in a direction opposite to the first direction DR1 from the first main portion PXE3-1. In one or more embodiments, the first extending portion PXE3-2 may be bent toward the second direction DR2 in a plan view.

In one or more embodiments, the first main portion PXE3-1 may overlap the third pixel circuit PC3 in a plan view. In one or more embodiments, the first main portion PXE3-1 may overlap a portion of the third connection electrode CNE3 in a plan view. For example, a portion of the first main portion PXE3-1 may contact a portion of the third connection electrode CNE3 through the contact hole of the second via insulating layer VIA2.

In one or more embodiments, the first extending portion PXE3-2 may overlap the first pixel circuit PC1 and the second pixel circuit PC2 in a plan view. For example, the first extending portion PXE3-2 may extend in a direction opposite to the first direction DR1 and pass over an upper portion of each of the first pixel circuit PC1 and the second pixel circuit PC2.

In one or more embodiments, the first extending portion PXE3-2 may extend along a portion of a boundary of the sixth pixel electrode PXE6 adjacent to the first extending portion PXE3-2 in a plan view. For example, the first extending portion PXE3-2 may be around (e.g., may surround) a portion of the sixth pixel electrode PXE6 adjacent to the first extending portion PXE3-2 while maintaining a constant distance between the portion of the sixth pixel electrode PXE6 and the first extending portion PXE3-2.

In one or more embodiments, in a plan view, the third pixel electrode PXE3 may be spaced (e.g., spaced apart) from the first pixel electrode PXE1 in the opposite direction of the second direction DR2. For example, the first main portion PXE3-1 may be disposed in the opposite direction of the second direction DR2 from the first portion of the first pixel electrode PXE1.

The fourth pixel electrode PXE4 may be electrically connected to the fourth pixel circuit PC4. For example, the fourth pixel electrode PXE4 may be electrically connected to the fourth pixel circuit PC4 through the fourth connection electrode CNE4. Specifically, the fourth pixel electrode PXE4 may contact the fourth connection electrode CNE4 through a contact hole penetrating the second via insulating layer VIA2 in the thickness direction (e.g., the third direction DR3).

The fourth pixel electrode PXE4 may include a second main portion PXE4-1 and a second extending portion PXE4-2. The second main portion PXE4-1 and the second extending portion PXE4-2 may be formed integrally. In one or more embodiments, the second extending portion PXE4-2 may protrude from the second main portion PXE4-1 in a direction opposite to the first direction DR1. In one or more embodiments, the second extending portion PXE4-2 may be bent toward the second direction DR2 in a plan view.

In one or more embodiments, the second main portion PXE4-1 may overlap the sixth pixel circuit PC6 in a plan view. In one or more embodiments, the second extending portion PXE4-2 may overlap the fourth pixel circuit PC4 and the fifth pixel circuit PC5 in a plan view. For example, the second extending portion PXE4-2 may extend in a direction opposite to the first direction DR1 and pass over an upper portion of each of the fourth pixel circuit PC4 and the fifth pixel circuit PC5.

In one or more embodiments, the second extending portion PXE4-2 may extend along a portion of a boundary between the second extending portion PXE4-2 and the fifth pixel electrode PXE5 adjacent to the second extending portion PXE4-2 in a plan view. For example, in a plan view, the second extending portion PXE4-2 may be around (e.g., surround) a portion of the fifth pixel electrode PXE5 adjacent to the second extending portion PXE4-2 while maintaining a constant distance between the portion of the portion of the fifth pixel electrode PXE5 and the second extending portion PXE4-2.

In one or more embodiments, the second extending portion PXE4-2 may contact the fourth connection electrode CNE4 of the fourth pixel circuit PC4 through the contact hole of the second via insulating layer VIA2 from the sixth pixel circuit PC6 to the fifth pixel circuit PC5. As the second extending portion PXE4-2 contacts the fourth connection electrode CNE4, the fourth pixel electrode PXE4 and the fourth pixel circuit PC4 may be electrically connected to each other.

In one or more embodiments, in a plan view, the fourth pixel electrode PXE4 may be spaced (e.g., spaced apart) from each of the second pixel electrode PXE2 and the sixth pixel electrode PXE6 in a direction opposite to the second direction DR2. For example, the second main portion PXE4-1 may be disposed in a direction opposite to the second direction DR2 from the first portion of the second pixel electrode PXE2. In one or more embodiments, the fourth pixel electrode PXE4 may be spaced (e.g., spaced apart) from the sixth connection electrode CNE6 in a plan view.

The fifth pixel electrode PXE5 may be electrically connected to the fifth pixel circuit PC5. For example, the fifth pixel electrode PXE5 may be electrically connected to the fifth pixel circuit PC5 through the fifth connection electrode CNE5. Specifically, the fifth pixel electrode PXE5 may contact the fifth connection electrode CNE5 through a contact hole penetrating the second via insulating layer VIA2 in the thickness direction (e.g., the third direction DR3).

In one or more embodiments, the fifth pixel electrode PXE5 may overlap the fifth pixel circuit PC5 in a plan view. In one or more embodiments, the fifth pixel electrode PXE5 may overlap each of the fourth pixel circuit PC4 and the fifth pixel circuit PC5 in a plan view.

The sixth pixel electrode PXE6 may be electrically connected to the sixth pixel circuit PC6. For example, the sixth pixel electrode PXE6 may be electrically connected to the sixth pixel circuit PC6 through the sixth connection electrode CNE6. Specifically, the sixth pixel electrode PXE6 may contact the sixth connection electrode CNE6 through a contact hole penetrating the second via insulating layer VIA2 in the thickness direction (e.g., the third direction DR3).

The sixth pixel electrode PXE6 may include a third main portion PXE6-1 and a third extending portion PXE6-2. The third main portion PXE6-1 and the third extending portion PXE6-2 may be formed integrally. In one or more embodiments, the third extending portion PXE6-2 may protrude from the third main portion PXE6-1 in a direction opposite to the first direction DR1.

In one or more embodiments, the third main portion PXE6-1 may overlap the first pixel circuit PC1 and the second pixel circuit PC2 in a plan view. In one or more embodiments, the third extending portion PXE6-2 may overlap the second pixel circuit PC2 and the sixth pixel circuit PC6 in a plan view. For example, the third extending portion PXE6-2 may extend in a direction opposite to the first direction DR1 and pass over an upper portion of each of the second pixel circuit PC2 and the sixth pixel circuit PC6.

In one or more embodiments, the third extending portion PXE6-2 may be spaced (e.g., spaced apart) from the first portion of the second pixel electrode PXE2 in a direction opposite to the second direction DR2 in a plan view. In one or more embodiments, the third extending portion PXE6-2 may be spaced (e.g., spaced apart) from the second main portion PXE4-1 of the fourth pixel electrode PXE4 in the second direction DR2 in a plan view. In other words, the third extending portion PXE6-2 may be located between the first portion of the second pixel electrode PXE2 and the second main portion PXE4-1 of the fourth pixel electrode PXE4 in a plan view.

In one or more embodiments, the third extending portion PXE6-2 may extend from the upper portion of the second pixel circuit PC2 and may contact the sixth connection electrode CNE6 of the sixth pixel circuit PC6 through the contact hole of the second via insulating layer VIA2. As the third extending portion PXE6-2 contacts the sixth connection electrode CNE6, the sixth pixel electrode PXE6 and the sixth pixel circuit PC6 may be electrically connected to each other.

The seventh pixel electrode PXE7 may be electrically connected to the seventh pixel circuit PC7. For example, the seventh pixel electrode PXE7 may be electrically connected to the seventh pixel circuit PC7 through the seventh connection electrode CNE7. Specifically, the seventh pixel electrode PXE7 may contact the seventh connection electrode CNE7 through a contact hole penetrating the second via insulating layer VIA2 in the thickness direction (e.g., the third direction DR3).

In one or more embodiments, the seventh pixel electrode PXE7 may overlap the seventh pixel circuit PC7 in a plan view. In one or more embodiments, the seventh pixel electrode PXE7 may overlap the ninth pixel circuit PC9 in a plan view. Specifically, a first portion of the seventh pixel electrode PXE7 may overlap the ninth pixel circuit PC9 in a plan view, and a second portion of the seventh pixel electrode PXE7 protruding in a direction opposite to the first direction DR1 from the first portion may overlap the seventh pixel circuit PC7 in a plan view. In addition, the first portion of the seventh pixel electrode PXE7 may overlap a portion of the ninth connection electrode CNE9 in a plan view.

The eighth pixel electrode PXE8 may be electrically connected to the eighth pixel circuit PC8. For example, the eighth pixel electrode PXE8 may be electrically connected to the eighth pixel circuit PC8 through the eighth connection electrode CNE8. Specifically, the eighth pixel electrode PXE8 may contact the eighth connection electrode CNE8 through a contact hole penetrating the second via insulating layer VIA2 in the thickness direction (e.g., the third direction DR3).

In one or more embodiments, the eighth pixel electrode PXE8 may overlap the eighth pixel circuit PC8 in a plan view. In one or more embodiments, the eighth pixel electrode PXE8 may overlap the eighth pixel circuit PC8 in a plan view.

Specifically, a first portion of the eighth pixel electrode PXE8 may overlap the twelfth pixel circuit PC12 in a plan view, and a second portion of the eighth pixel electrode PXE8 protruding in the first direction DR1 from the first portion may overlap the eighth pixel circuit PC8 in a plan view. In addition, the first portion of the eighth pixel electrode PXE8 may overlap a portion of the twelfth connection electrode CNE12 in a plan view.

In one or more embodiments, in a plan view, the eighth pixel electrode PXE8 disposed in the first direction DR1 from the seventh pixel electrode PXE7 may contact the tenth pixel circuit PC10 and the eleventh pixel circuit PC11 and may be symmetrical with the seventh pixel electrode PXE7 based on an virtual line parallel to the second direction DR2. In one or more embodiments, in a plan view, the eighth pixel electrode PXE8 disposed in the opposite direction from the seventh pixel electrode PXE7 in the first direction DR1 may be symmetrical with the seventh pixel electrode PXE7 based on the first data line DL1.

The ninth pixel electrode PXE9 may be electrically connected to the ninth pixel circuit PC9. For example, the ninth pixel electrode PXE9 may be electrically connected to the ninth pixel circuit PC9 through the ninth connection electrode CNE9. Specifically, the ninth pixel electrode PXE9 may contact the ninth connection electrode CNE9 through a contact hole penetrating the second via insulating layer VIA2 in the thickness direction (e.g., the third direction DR3).

The ninth pixel electrode PXE9 may include a fourth main portion PXE9-1 and a fourth extending portion PXE9-2. The fourth main portion PXE9-1 and the fourth extending portion PXE9-2 may be formed integrally. In one or more embodiments, the fourth extending portion PXE9-2 may protrude from the fourth main portion PXE9-1 in a direction opposite to the first direction DR1. In one or more embodiments, the fourth extending portion PXE9-2 may be bent toward the second direction DR2 in a plan view.

In one or more embodiments, the fourth main portion PXE9-1 may overlap the ninth pixel circuit PC9 in a plan view. In one or more embodiments, the fourth main portion PXE9-1 may overlap a portion of the ninth connection electrode CNE9 in a plan view. For example, a portion of the fourth main portion PXE9-1 may contact a portion of the ninth connection electrode CNE9 through the contact hole of the second via insulating layer VIA2.

In one or more embodiments, the fourth extending portion PXE9-2 may overlap the ninth pixel circuit PC9 and the seventh pixel circuit PC7 in a plan view. For example, the fourth extending portion PXE9-2 may extend in a direction opposite to the first direction DR1 and pass over an upper portion of the ninth pixel circuit PC9. In addition, the fourth extending portion PXE9-2 may extend in a direction opposite to the first direction DR1 and may be bent in a second direction DR2 to pass through an upper portion of the seventh pixel circuit PC7.

In one or more embodiments, the fourth extending portion PXE9-2 may be adjacent to a portion of the twelfth pixel electrode PXE12. For example, the fourth extending portion PXE9-2 may be spaced (e.g., spaced apart) from the twelfth pixel electrode PXE12 in the first direction DR1 in a plan view, while maintaining a constant distance from a portion of a boundary of the twelfth pixel electrode PXE12.

In one or more embodiments, the ninth pixel electrode PXE9 may be spaced (e.g., spaced apart) from the seventh pixel electrode PXE7 in a direction opposite to the second direction DR2 in a plan view. For example, the fourth main portion PXE9-1 may be disposed in the opposite direction DR2 from the first portion of the seventh pixel electrode PXE7.

The tenth pixel electrode PXE10 may be electrically connected to the tenth pixel circuit PC10. For example, the tenth pixel electrode PXE10 may be electrically connected to the tenth pixel circuit PC10 through the tenth connection electrode CNE10. Specifically, the tenth pixel electrode PXE10 may contact the tenth connection electrode CNE10 through a contact hole penetrating the second via insulating layer VIA2 in the thickness direction.

The tenth pixel electrode PXE10 may include a fifth main portion PXE10-1 and a fifth extending portion PXE10-2. The fifth main portion PXE10-1 and the fifth extending portion PXE10-2 may be formed integrally. In one or more embodiments, the fifth extending portion PXE10-2 may protrude in a direction opposite to the first direction DR1 from the fifth main portion PXE10-1. In one or more embodiments, the fifth extending portion PXE10-2 may be bent toward the second direction DR2 in a plan view.

In one or more embodiments, the fifth main portion PXE10-1 may overlap the twelfth pixel circuit PC12 in a plan view. In one or more embodiments, the fifth extending portion PXE10-2 may overlap the tenth pixel circuit PC10 and the eleventh pixel circuit PC11 in a plan view. For example, the fifth extending portion PXE10-2 may extend in a direction opposite to the first direction DR1 and pass over the upper portions of each of the tenth pixel circuit PC10 and the eleventh pixel circuit PC11.

In one or more embodiments, the fifth extending PXE10-2 may extend along a portion of a boundary between the fifth extending PXE10-2 and the fifth pixel electrode PXE5 adjacent to the fifth extending PXE10-2 in a plan view. For example, in a plan view, the fifth extending PXE10-2 may be around (e.g., may surround) a portion of the eleventh pixel electrode PXE11 adjacent to the fifth extending PXE10-2 while maintaining a constant distance between the portion of the eleventh pixel electrode PXE11 and the fifth extending portion PXE10-2.

In one or more embodiments, the fifth extending PXE10-2 may contact the tenth connection electrode CNE10 of the tenth pixel circuit PC10 through the contact hole of the second via insulating layer VIA2 from the twelfth pixel circuit PC12 to the eleventh pixel circuit PC11. As the fifth extending portion PXE10-2 comes into contact with the tenth connection electrode CNE10, the tenth pixel electrode PXE10 and the tenth pixel circuit PC10 may be electrically connected to each other.

In one or more embodiments, in a plan view, the tenth pixel electrode PXE10 may be spaced (e.g., spaced apart) from each of the eighth pixel electrode PXE8 and the twelfth pixel electrode PXE12 in a direction opposite to the second direction DR2. For example, the fifth main portion PXE10-1 may be disposed in a direction opposite to the second direction DR2 from the first portion of the eighth pixel electrode PXE8. In one or more embodiments, the tenth pixel electrode PXE10 may be spaced (e.g., spaced apart) from the twelfth connection electrode CNE12 in a plan view.

The eleventh pixel electrode PXE11 may be electrically connected to the eleventh pixel circuit PC11. For example, the eleventh pixel electrode PXE11 may be electrically connected to the eleventh pixel circuit PC11 through the eleventh connection electrode CNE11. Specifically, the eleventh pixel electrode PXE11 may contact the eleventh connection electrode CNE11 through a contact hole that penetrates the second via insulating layer VIA2 in the thickness direction (e.g., the third direction DR3).

In one or more embodiments, the eleventh pixel electrode PXE11 may overlap the eleventh pixel circuit PC11 in a plan view. In one or more embodiments, the eleventh pixel electrode PXE11 may overlap each of the tenth pixel circuit PC10 and the eleventh pixel circuit PC11 in a plan view.

The twelfth pixel electrode PXE12 may include a sixth main portion PXE12-1 and a sixth extending portion PXE12-2. The sixth main portion PXE12-1 and the sixth extending portion PXE12-2 may be formed integrally. In one or more embodiments, the sixth extending portion PXE12-2 may protrude in a direction opposite to the first direction DR1 from the sixth main portion PXE12-1.

In one or more embodiments, the sixth main portion PXE12-1 may overlap the seventh pixel circuit PC7 and the eighth pixel circuit PC8 in a plan view. In one or more embodiments, the sixth extending portion PXE12-2 may overlap the eighth pixel circuit PC8 and the twelfth pixel circuit PC12 in a plan view. For example, the sixth extending portion PXE12-2 may extend in a direction opposite to the first direction DR1 and pass over the upper portions of each of the eighth pixel circuit PC8 and the twelfth pixel circuit PC12.

In one or more embodiments, the sixth extending portion PXE12-2 may be spaced (e.g., spaced apart) from the first portion of the eighth pixel electrode PXE8 in the opposite direction of the second direction DR2 in a plan view. In one or more embodiments, the sixth extending portion PXE12-2 may be spaced (e.g., spaced apart) from the fifth main portion PXE10-1 of the tenth pixel electrode PXE10 in the second direction DR2 in a plan view. In other words, the sixth extending portion PXE12-2 may be located between the first portion of the eighth pixel electrode PXE8 and the fifth main portion PXE10-1 of the tenth pixel electrode PXE10 in a plan view.

In one or more embodiments, the sixth extending portion PXE12-2 may extend from the upper portion of the eighth pixel circuit PC8 and may contact the twelfth connection electrode CNE12 of the twelfth pixel circuit PC12 through the contact hole of the second via insulating layer VIA2. As the sixth extending portion PXE12-2 contacts the twelfth connection electrode CNE12, the twelfth pixel electrode PXE12 and the twelfth pixel circuit PC12 may be electrically connected to each other.

In one or more embodiments, the pixel electrodes disposed in one row may be regularly disposed along the first direction DR1. For example, the pixel electrodes disposed in the Nth row R(N) may be disposed in an order of the second pixel electrode PXE2, the first pixel electrode PXE1, the third pixel electrode PXE3, the fourth pixel electrode PXE4, the fifth pixel electrode PXE5, and the sixth pixel electrode PXE6. In addition, the pixel electrodes disposed in the N+1th row R(N+1) may be disposed in an order of the eighth pixel electrode PXE8, the seventh pixel electrode PXE7, the ninth pixel electrode PXE9, the tenth pixel electrode PXE10, the eleventh pixel electrode PXE11, and the twelfth pixel electrode PXE12.

In one or more embodiments, an arrangement of pixel electrodes disposed in the Nth row R(N) and an arrangement of pixel electrodes disposed in the N+1th row R(N+1) may be repeated along the second direction DR2. For example, the arrangement of pixel electrodes disposed in the Nth row R(N) and the arrangement of pixel electrodes disposed in the N+1th row R(N+1) may be disposed alternately along the second direction DR2.

In one or more embodiments, the first auxiliary electrode AXE1 may be disposed between the sixth pixel electrode PXE6 and the twelfth pixel electrode PXE12 in a plan view. Specifically, the first auxiliary electrode AXE1 may be disposed between the third main portion PXE6-1 and the sixth main portion PXE12-1 in a plan view. In one or more embodiments, the first auxiliary electrode AXE1 may overlap the first pixel circuit PC1, the second pixel circuit PC2, the seventh pixel circuit PC7, and the eighth pixel circuit PC8 in a plan view. In one or more embodiments, the first auxiliary electrode AXE1 may overlap the first data line DL1 in a plan view.

In one or more embodiments, the first auxiliary electrode AXE1 may be disposed along the first direction DR1 and the second direction DR2 in multiple numbers. A thirteenth hole H13 may be defined in a pixel defining layer PDL covering an upper portion of some electrodes from among the plurality of first auxiliary electrodes. The thirteenth hole H13 may not be defined in a pixel defining layer PDL covering an upper portions of remaining electrodes from among the plurality of first auxiliary electrodes.

In one or more embodiments, the second auxiliary electrode AXE2 may be disposed in an opposite direction from the fifth pixel electrode PXE5 in the second direction DR2. For example, the second auxiliary electrode AXE2 may be spaced (e.g., spaced apart) from each of the second extending portion PXE4-2 of the fourth pixel electrode PXE4-2 and the fifth pixel electrode PXE5 in an opposite direction from the second direction DR2.

In one or more embodiments, the second auxiliary electrode AXE2 may be disposed in the second direction DR2 from the eleventh pixel electrode PXE11. For example, the second auxiliary electrode AXE2 may be spaced (e.g., spaced apart) from each of the eleventh pixel electrodes PXE11 in the second direction DR2. In one or more embodiments, the second auxiliary electrodes AXE2 may be repeatedly disposed along the second direction DR2. For example, the second auxiliary electrodes (AXE2) may be disposed in a plurality of rows with one row as an interval.

In one or more embodiments, the first auxiliary electrode AXE1 and the second auxiliary electrode AXE2 may have a same shape in a plan view. However, the shapes of the first auxiliary electrode AXE1 and the second auxiliary electrode AXE2 according to the present disclosure may not be necessarily limited thereto, and a shape of each of the first auxiliary electrode AXE1 and the second auxiliary electrode AXE2 may be different from each other in a plan view.

The pixel defining layer PDL may be disposed on the pixel electrode layer PXL. In one or more embodiments, the pixel defining layer PDL may include an organic insulating material, such as polyimide. The light-emitting layer EML may be disposed on the pixel defining layer PDL. In one or more embodiments, the light-emitting layer EML may include a light emitting material. For example, the light emitting material may include an organic light emitting material, a quantum dot, and/or the like. The common electrode CME may be disposed on the light-emitting layer EML. For example, the common electrode CME may be disposed on the light-emitting layer EML and the pixel defining layer PDL. In one or more embodiments, the common electrode CME may include a conductive material.

At least one hole may be defined in the pixel defining layer PDL to expose a portion of an upper surface of each of the first pixel electrode PXE1, the second pixel electrode PXE2, the third pixel electrode PXE3, the fourth pixel electrode PXE4, the fifth pixel electrode PXE5, the sixth pixel electrode PXE6, the seventh pixel electrode PXE7, the eighth pixel electrode PXE8, the ninth pixel electrode PXE9, the tenth pixel electrode PXE10, the eleventh pixel electrode PXE11, the twelfth pixel electrode PXE12, and the first auxiliary electrode AXE1.

In one or more embodiments, the hole may penetrate the pixel defining layer PDL in the thickness direction (e.g., in the third direction DR3). The hole may include a first hole H1, a second hole H2, a third hole H3, a fourth hole H4, a fifth hole H5, a sixth hole H6, a seventh hole H7, an eighth hole H8, a ninth hole H9, a tenth hole H10, an eleventh hole H11, a twelfth hole H12, and the thirteenth hole H13.

In one or more embodiments, the first hole H1 may expose a portion of an upper surface of the first pixel electrode PXE1. For example, the first hole H1 may expose the first portion of the first pixel electrode PXE1.

In one or more embodiments, the first light-emitting layer EML1 may fill the first hole H1. As described above, the first light-emitting layer EML1 may define the first light-emitting element EL1 that emits light of a first color together with the first pixel electrode PXE1 and the common electrode CME. In one or more embodiments, the first light-emitting layer EML1 may overlap the third pixel circuit PC3 in a plan view.

In one or more embodiments, the second hole H2 may expose a portion of an upper surface of the second pixel electrode PXE2. For example, the second hole H2 may expose the first portion of the second pixel electrode PXE2.

In one or more embodiments, the second light-emitting layer EML2 may fill the second hole H2. For example, the second light-emitting layer EML2 may define a light-emitting element that emits light of the first color together with the second pixel electrode PXE2 and the common electrode CME. In one or more embodiments, the second light-emitting layer EML2 may overlap the sixth pixel circuit PC6 in a plan view.

In one or more embodiments, the third hole H3 may expose a portion of an upper surface of the third pixel electrode PXE3. For example, the third hole H3 may expose the first main portion PXE3-1 of the third pixel electrode PXE3.

In one or more embodiments, the third light-emitting layer EML3 may fill the third hole H3. For example, the third light-emitting layer EML3 may define a light-emitting element that emits light of a second color together with the third pixel electrode PXE3 and the common electrode CME. In one or more embodiments, the third light-emitting layer EML3 may overlap the third pixel circuit PC3 and the first main portion PXE3-1 in a plan view.

In one or more embodiments, the fourth hole H4 may expose a portion of an upper surface of the fourth pixel electrode PXE4. For example, the fourth hole H4 may expose the second main portion PXE4-1 of the fourth pixel electrode PXE4.

In one or more embodiments, the fourth light-emitting layer EML4 may fill the fourth hole H4. For example, the fourth light-emitting layer EML4 may define a light-emitting element that emits light of the second color together with the fourth pixel electrode PXE4 and the common electrode CME. In one or more embodiments, the fourth light-emitting layer EML4 may overlap the sixth pixel circuit PC6 and the second main portion PXE4-1 in a plan view.

In one or more embodiments, the fifth hole H5 may expose a portion of an upper surface of the fifth pixel electrode PXE5. In one or more embodiments, the fifth light-emitting layer EML5 may fill the fifth hole H5. For example, the fifth light-emitting layer EML5 may define a light-emitting element that emits light of the third color together with the fifth pixel electrode PXE5 and the common electrode CME. In an embodiment, the fifth light-emitting layer EML5 may overlap the fourth pixel circuit PC4 and the fifth pixel circuit PC5 in a plan view.

In one or more embodiments, the sixth hole H6 may expose a portion of an upper surface of the sixth pixel electrode PXE6. For example, the sixth hole H6 may expose the third main portion PXE6-1 of the sixth pixel electrode PXE6.

In one or more embodiments, the sixth light-emitting layer EML6 may fill the sixth hole H6. For example, the sixth light-emitting layer EML6 may define a light-emitting element that emits light of the third color together with the sixth pixel electrode PXE6 and the common electrode CME. In one or more embodiments, the sixth light-emitting layer EML6 may overlap the first pixel circuit PC1 and the second pixel circuit PC2 in a plan view. In one or more embodiments, the sixth light-emitting layer EML6 may overlap the third main portion PXE6-1 in a plan view.

In one or more embodiments, the seventh hole H7 may expose a portion of an upper surface of the seventh pixel electrode PXE7. For example, the seventh hole H7 may expose the first portion of the seventh pixel electrode PXE7.

In one or more embodiments, the seventh light-emitting layer EML7 may fill the seventh hole H7. For example, the seventh light-emitting layer EML7 may define a light-emitting element that emits light of the first color together with the seventh pixel electrode PXE7 and the common electrode CME. In one or more embodiments, the seventh light-emitting layer EML7 may overlap the ninth pixel circuit PC9 in a plan view.

In one or more embodiments, the eighth hole H8 may expose a portion of an upper surface of the eighth pixel electrode PXE8. For example, the eighth hole H8 may expose the first portion of the eighth pixel electrode PXE8.

In one or more embodiments, the eighth light-emitting layer EML8 may fill the eighth hole H8. For example, the eighth light-emitting layer EML8 may define a light-emitting element that emits light of the first color together with the eighth pixel electrode PXE8 and the common electrode CME. In one or more embodiments, the eighth light-emitting layer EML8 may overlap the twelfth pixel circuit PC12 in a plan view.

In one or more embodiments, the ninth hole H9 may expose a portion of an upper surface of the ninth pixel electrode PXE9. For example, the ninth hole H9 may expose the fourth main portion PXE9-1 of the ninth pixel electrode PXE9.

In one or more embodiments, the ninth light-emitting layer EML9 may fill the ninth hole H9. For example, the ninth light-emitting layer EML9 may define a light-emitting element that emits light of the second color together with the ninth pixel electrode PXE9 and the common electrode CME. In one or more embodiments, the ninth light-emitting layer EML9 may overlap the ninth pixel circuit (PC9) and the fourth main portion PXE9-1 in a plan view.

In one or more embodiments, the tenth hole H10 may expose a portion of an upper surface of the tenth pixel electrode PXE10. For example, the tenth hole H10 may expose the fifth main portion PXE10-1 of the tenth pixel electrode PXE10.

In one or more embodiments, the tenth light-emitting layer EML10 may fill the tenth hole H10. For example, the tenth light-emitting layer EML10 may define a light-emitting element that emits light of the second color together with the tenth pixel electrode PXE10 and the common electrode CME. In one or more embodiments, the tenth light-emitting layer EML10 may overlap the twelfth pixel circuit PC12 and the fifth main portion PXE10-1 in a plan view.

In one or more embodiments, the eleventh hole H11 may expose a portion of the upper surface of the eleventh pixel electrode PXE11. In one or more embodiments, the eleventh light-emitting layer EML11 may fill the eleventh hole H11. For example, the eleventh light-emitting layer EML11 may define a light-emitting element that emits light of the third color together with the eleventh pixel electrode PXE11 and the common electrode CME. In one or more embodiments, the eleventh light-emitting layer EML11 may overlap the tenth pixel circuit PC10 and the eleventh pixel circuit PC11 in a plan view.

In one or more embodiments, the twelfth hole H12 may expose a portion of the upper surface of the twelfth pixel electrode PXE12. For example, the twelfth hole H12 may expose the sixth main portion PXE12-1 of the twelfth pixel electrode PXE12.

In one or more embodiments, the twelfth light-emitting layer EML12 may fill the twelfth hole H12. For example, the twelfth light-emitting layer EML12 may define a light-emitting element that emits light of the third color together with the twelfth pixel electrode PXE12 and the common electrode CME. In one or more embodiments, the twelfth light-emitting layer EML12 may overlap the seventh pixel circuit PC7 and the eighth pixel circuit PC8 in a plan view. In one or more embodiments, the twelfth light-emitting layer EML12 may overlap the sixth main portion PXE12-1 in a plan view.

In one or more embodiments, a thirteenth hole H13 that exposes a portion of the upper surface of the first auxiliary electrode AXE1 may be defined in the pixel definition film PDL covering the first auxiliary electrode AXE1. In one or more embodiments, the thirteenth hole H13 may expose a portion of an upper surface of the first auxiliary electrode AXE1.

In one or more embodiments, the common electrode CME may be electrically connected to the first auxiliary electrode AXE1 through the thirteenth hole H13. Accordingly, a voltage drop phenomenon of the first power voltage (e.g., the first power voltage ELVDD of FIG. 3) applied to the common electrode CME may be prevented.

In one or more embodiments, the thirteenth hole H13 may be formed through a laser drilling process. However, the light-emitting layer EML and the thirteenth hole H13 according to the present disclosure may not be necessarily limited thereto. For example, the light-emitting layer EML may be formed to entirely surround the upper portion of the pixel defining layer PDL, and the thirteenth hole H13 may penetrate each of the pixel defining layer PDL and the light-emitting layer EML in the thickness direction (e.g., the third direction DR3).

In one or more embodiments, the first auxiliary electrode AXE1 may be disposed along the first direction DR1 and the second direction DR2 in multiple numbers. In one or more embodiments, a plurality of second auxiliary electrodes AXE2 may be disposed along the first direction DR1 and the second direction DR2. In one or more embodiments, the pixel defining layer PDL may cover the entire upper surface of each of the plurality of second auxiliary electrodes AXE2.

In one or more embodiments, the number of thirteenth holes H13 may be the same as the number of first auxiliary electrodes AXE1. For example, the plurality of first auxiliary electrodes may be disposed along the first direction DR1 and the second direction DR2, and the thirteenth hole H13 may be disposed at each located where each of the plurality of first auxiliary electrodes is disposed.

In another embodiment, a number of thirteenth hole H13 may be less than the number of first auxiliary electrodes AXE1. For example, the thirteenth hole H13 may be disposed at each location where each of the auxiliary electrodes of the plurality of first auxiliary electrodes is disposed. For example, one of the thirteenth hole H13 may be disposed at each of two or more first auxiliary electrodes that are adjacent to each other in the first direction DR1 or the second direction DR2.

As described above, in the display device 1 according to the present disclosure, the data voltage VDATA may be provided to each of the pixels included in the first pixel group PXG1 through the first write gate line GWL1 to which the first write gate signal GW1 is applied. In addition, a data voltage VDATA may be provided to each of the pixels included in the second pixel group PXG2 disposed in a same row as the pixels included in the first pixel group PXG1 through a second write gate line GWL2 to which a second write gate signal GW2 is applied at a different timing at which the first write gate signal GW1 is applied. Accordingly, the display device 1 may selectively output the data voltage VDATA to one of the plurality of pixels disposed in a same row without including a demultiplexer circuit that selectively outputs the data voltage VDATA to one of the plurality of pixels disposed in a same row. Accordingly, a power consumption efficiency of the display device is improved, and a number of pixels disposed in the display area DA of the display device 1 may be increased, and display quality may be improved.

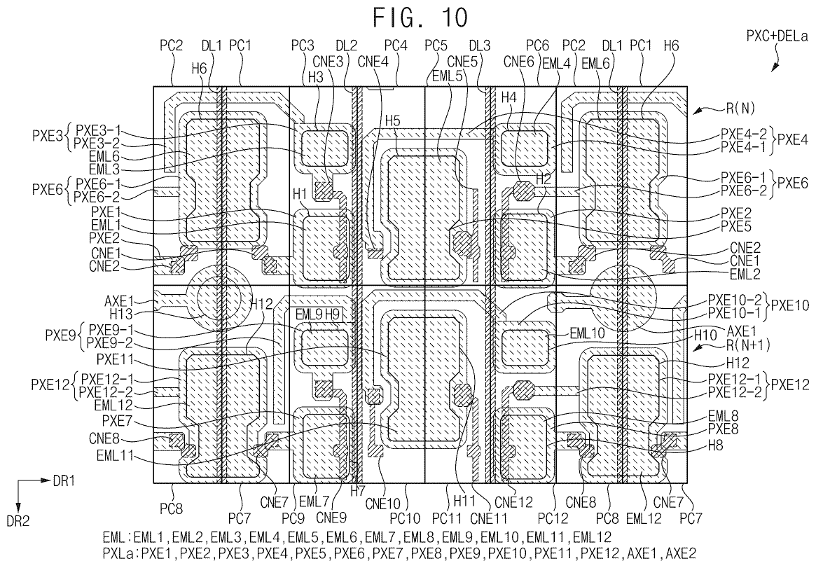

FIG. 10 is a layout diagram illustrating another example of an arrangement of components of the pixels included in the display panel of FIG. 1.

The display device described with reference to FIG. 10 may be substantially the same as or similar to the display device described with reference to FIG. 8, except that the second auxiliary electrode AXE2 is omitted from the light-emitting element layer DEL of FIG. 8.

Hereinafter, contents overlapping with those described with reference to FIGS. 1, 2, 3, 4, 5, 6, 7, 8, and 9 may be omitted or briefly described.

Referring to FIG. 10, a light-emitting element layer DELa may include a pixel electrode layer PXLa, the pixel defining layer PDL, the light-emitting layer EML, and the common electrode CME. The pixel electrode layer PXLa may include the first pixel electrode PXE1, the second pixel electrode PXE2, the third pixel electrode PXE3, the fourth pixel electrode PXE4, the fifth pixel electrode PXE5, the sixth pixel electrode PXE6, the seventh pixel electrode PXE7, the eighth pixel electrode PXE8, the ninth pixel electrode PXE9, the tenth pixel electrode PXE10, the eleventh pixel electrode PXE11, the twelfth pixel electrode PXE12, the first auxiliary electrode AXE1, and the second auxiliary electrode AXE2.

In one or more embodiments, auxiliary electrodes may not be disposed in rows where the fourth pixel circuit PC4 and the fifth pixel circuit PC5 are disposed. For example, components of the pixel electrode layer PXLa disposed along columns in which the fourth pixel circuit PC4 and the fifth pixel circuit PC5 are disposed may be disposed along the second direction DR2 in an order of the second extending portion PXE4-2 of the fourth pixel electrode PXE4, the fifth pixel electrode PXE5, the fifth extending portion PXE10-2 of the tenth pixel electrode PXE10, and the eleventh pixel electrode PXE11. In other words, the second auxiliary electrode AXE2 of FIG. 8 may not be disposed on the fourth pixel circuit PC4, the fifth pixel circuit PC5, the tenth pixel circuit PC10, and the eleventh pixel circuit PC11. Accordingly, an area where the second extending portion PXE4-2 of the fourth pixel electrode PXE4 is disposed on the pixel circuit layer PXC may be easily secured, and time and cost in the manufacturing process of the display device 1 of FIG. 1 may be reduced.

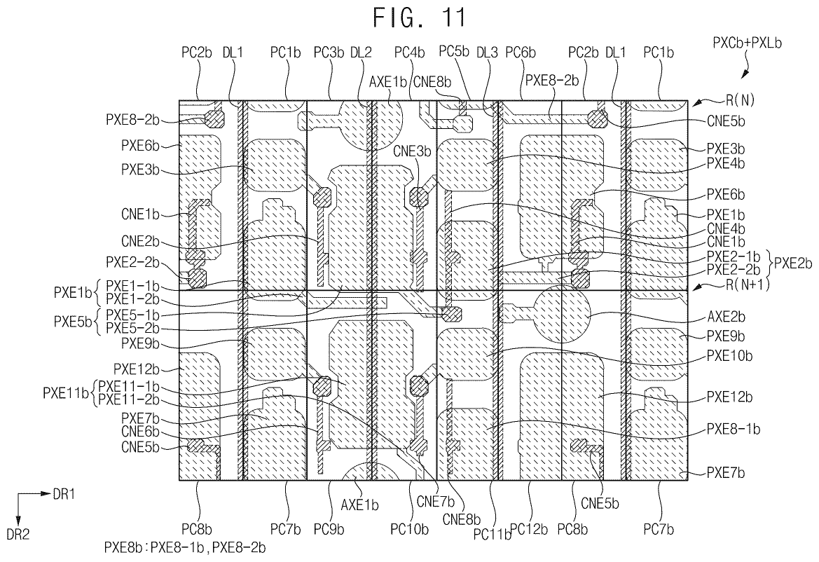

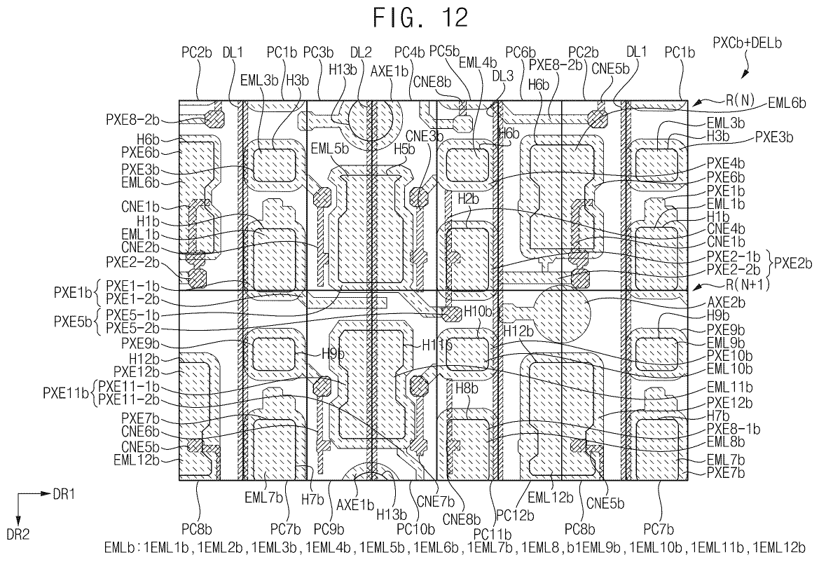

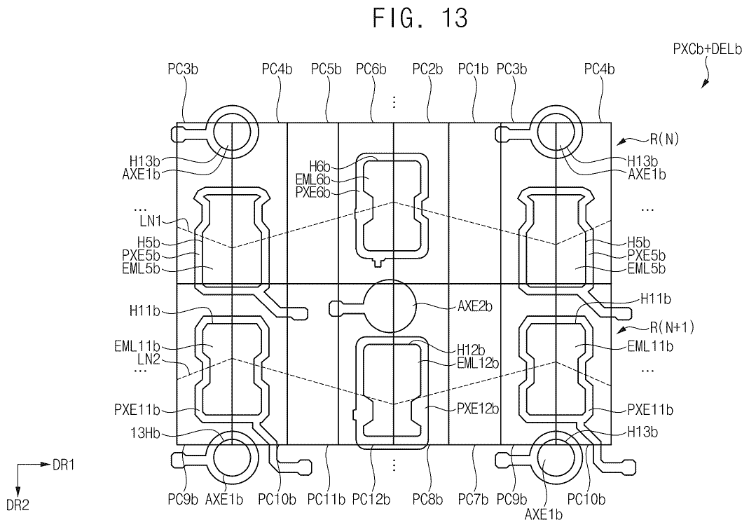

FIGS. 11 and 12 are layout diagrams illustrating still another example of an arrangement of components of the pixels included in the display panel of FIG. 1. FIG. 13 is a plan view explaining for an example of an arrangement of a pixel electrode and an auxiliary electrode of FIG. 12. For example, FIG. 13 is a plan view illustrating a pixel circuit layer PXCb, a fifth pixel electrode PXE5b, a sixth pixel electrode PXE6b, a eleventh pixel electrode PXE11b, a twelfth pixel electrode PXE12b, a first auxiliary electrode AXE1b, and a second auxiliary electrode AXE2b of FIG. 12.

The display device described with reference to FIGS. 11 and 12 may be substantially the same as or similar to the display device described with reference to FIG. 8, except for arrangement and shape of the components included in the pixel circuit layer PXCb and the light-emitting element layer DELb.

Hereinafter, any content overlapping with the content described with reference to FIGS. 1, 2, 3, 4, 5, 6, 7, 8, and 9 may be omitted or briefly described.

Referring to FIGS. 11, 12, and 13, a pixel circuit layer PXCb may include a first pixel circuit PC1b, a second pixel circuit PC2b, a third pixel circuit PC3b, a fourth pixel circuit PC4b, a fifth pixel circuit PC5b, a sixth pixel circuit PC6b, a seventh pixel circuit PC7b, an eighth pixel circuit PC8b, a ninth pixel circuit PC9b, a tenth pixel circuit PC10b, an eleventh pixel circuit PC11b, and a twelfth pixel circuit PC12b.

The second pixel circuit PC2b may include a first connection electrode CNE1b. The third pixel circuit PC3b may include a second connection electrode CNE2b. The fourth pixel circuit PC4b may include a third connection electrode CNE3b. The fifth pixel circuit PC5b may include a fourth connection electrode CNE4b. The eighth pixel circuit PC8b may include a fifth connection electrode CNE5b. The ninth pixel circuit PC9b may include a sixth connection electrode CNE6b. The tenth pixel circuit PC10b may include a seventh connection electrode CNE7b. The eleventh pixel circuit PC11b may include an eighth connection electrode CNE8b.

In one or more embodiments, the fourth connection electrode CNE4b may overlap each of the fifth pixel circuit PC5b and the eleventh pixel circuit PC11b in a plan view. In one or more embodiments, the fifth connection electrode CNE5b may overlap each of the second pixel circuit PC2b and the eighth pixel circuit PC8b in a plan view (e.g., see FIG. 11).

The pixel electrode layer PXLb may include a first pixel electrode PXE1b, a second pixel electrode PXE2b, a third pixel electrode PXE3b, a fourth pixel electrode PXE4b, a fifth pixel electrode PXE5b, a sixth pixel electrode PXE6b, a seventh pixel electrode PXE7b, an eighth pixel electrode PXE8b, a ninth pixel electrode PXE9b, a tenth pixel electrode PXE10b, an eleventh pixel electrode PXE11b, a twelfth pixel electrode PXE12b, a first auxiliary electrode AXE1b, and a second auxiliary electrode AXE2b.

The first pixel electrode PXE1b may include a first main portion PXE1-1b and a first extending portion PXE1-2b. In one or more embodiments, the first main portion PXE1-1b may overlap each of the first pixel circuit PC1b and the seventh pixel circuit PC7b in a plan view. In one or more embodiments, the first extending portion PXE1-2b may extend from the first main portion PXE1-1b in the first direction DR1 and may overlap each of the ninth pixel circuit PC9b and the tenth pixel circuit PC10b in a plan view.

The second pixel electrode PXE2b may include the second main portion PXE2-1b and the second extending portion PXE2-2b. In one or more embodiments, the second main portion PXE2-1b may overlap the fifth pixel circuit PC5b and the eleventh pixel circuit PC11b in a plan view. In one or more embodiments, the second main portion PXE2-1b may overlap the fourth connection electrode CNE4b in a plan view.

In one or more embodiments, the second extending portion PXE2-2b may extend from the second main portion PXE2-1b in a first direction DR1 and may overlap each of the second pixel circuit PC2b and the sixth pixel circuit PC6b in a plan view. For example, the second extending portion PXE2-2b may overlap the first connection electrode CNE1b in a plan view. Specifically, the second extending portion PXE2-2b extended from the second main portion PXE2-1b in the first direction DR1 may contact the first connection electrode CNE1b through a contact hole penetrating the first via insulating layer (e.g., the first via insulating layer VIA1 of FIG. 9) in the thickness direction (e.g., the third direction DR3). Accordingly, the second pixel electrode PXE2b may be electrically connected to the second pixel circuit PC2b via the first connection electrode CNE1b.

In one or more embodiments, the third pixel electrode PXE3b may overlap each of the first pixel circuit PC1b and the third pixel circuit PC3b in a plan view. For example, a first portion of the third pixel electrode PXE3b may overlap the first pixel circuit PC1b in a plan view, and a second portion extending from the first portion of the third pixel electrode PXE3b in a diagonal direction in the first direction DR1 and the second direction DR2 may overlap the third pixel circuit PC3b in a plan view.

The third pixel electrode PXE3b may be electrically connected to the third pixel circuit PC3b via the second connection electrode CNE2b. Specifically, the second portion of the third pixel electrode PXE3b may contact the second connection electrode CNE2b through a contact hole penetrating the first via insulating layer in the thickness direction (e.g., the third direction DR3).

In one or more embodiments, the fourth pixel electrode PXE4b may overlap each of the fourth pixel circuit PC4b and the fifth pixel circuit PC5b in a plan view. For example, the first portion of the fourth pixel electrode PXE4b may overlap the fifth pixel circuit PC5b in a plan view, and the second portion extending from the first portion of the fourth pixel electrode PXE4b in the opposite direction of the first direction DR1 and in the diagonal direction of the second direction DR2 may overlap the fourth pixel circuit PC4b in a plan view.

The fourth pixel electrode PXE4b may be electrically connected to the fourth pixel circuit PC4b through the third connection electrode CNE3b. Specifically, the second portion of the fourth pixel electrode PXE4b may contact the third connection electrode CNE3b through a contact hole penetrating the first via insulating layer in the thickness direction (e.g., the third direction DR3).

The fifth pixel electrode PXE5b may include a third main portion PXE5-1b and a third extending portion PXE5-2b. In one or more embodiments, the third main portion PXE5-1b may overlap each of the third pixel circuit PC3b and the fourth pixel circuit PC4b in a plan view.

In one or more embodiments, the third extending portion PXE5-2b may extend in the diagonal direction of the first direction DR1 and the second direction DR2 from the third main portion PXE5-1b. In one or more embodiments, the third extending portion PXE5-2b may overlap each of the tenth pixel circuit PC10b and the eleventh pixel circuit PC11b in a plan view.

The fifth pixel electrode PXE5b may be electrically connected to the fifth pixel circuit PC5b through the fourth connection electrode CNE4b. Specifically, the third extending portion PXE5-2b of the fifth pixel electrode PXE5b may contact the fourth connection electrode CNE4b through a contact hole penetrating the first via insulating layer in the thickness direction (e.g., the third direction DR3).

In one or more embodiments, the sixth pixel electrode PXE6b may overlap each of the second pixel circuit PC2b and the sixth pixel circuit PC6b in a plan view. In one or more embodiments, the sixth pixel electrode PXE6b may overlap the first connection electrode CNE1b in a plan view.

In one or more embodiments, the seventh pixel electrode PXE7b may overlap the first pixel circuit PC1b and the seventh pixel circuit PC7b in a plan view. In one or more embodiments, the shape of the first pixel electrode PXE1b and the shape of the seventh pixel electrode PXE7b in a plan view may be different from each other.

The eighth pixel electrode PXE8b may include a fourth main portion PXE8-1b and a fourth extending portion PXE8-2b. In one or more embodiments, the fourth main portion PXE8-1b may overlap the fifth pixel circuit PC5b and the eleventh pixel circuit PC11b in a plan view.

In one or more embodiments, the fourth extending portion PXE8-2b may overlap the second pixel circuit PC2b and the sixth pixel circuit PC6b in a plan view. For example, the fourth extending portion PXE8-2b may extend from the fourth main portion PXE8-1b in the first direction DR1 and may overlap the second pixel circuit PC2b and the sixth pixel circuit PC6b in a plan view.

In one or more embodiments, the fourth extending portion PXE8-2b may overlap the fifth connection electrode CNE5b in a plan view. For example, the fourth extending portion PXE8-2b may contact the fifth connection electrode CNE5b through a contact hole penetrating the first via insulating layer in the thickness direction (e.g., the third direction DR3). Accordingly, the eighth pixel electrode PXE8b may be electrically connected to the eighth pixel circuit PC8b through the fifth connection electrode CNE5b.

The ninth pixel electrode PXE9b may be electrically connected to the ninth pixel circuit PC9b through the sixth connection electrode CNE6b. For example, the ninth pixel electrode PXE9b may contact the sixth connection electrode CNE6b through a contact hole penetrating the first via insulating layer in the thickness direction (e.g., the third direction DR3). In one or more embodiments, in a plan view, the shape of the third pixel electrode PXE3b may be substantially the same as the shape of the ninth pixel electrode PXE9b.

In one or more embodiments, the ninth pixel electrode PXE9b may overlap each of the seventh pixel circuit PC7b and the ninth pixel circuit PC9b in a plan view. For example, a first portion of the ninth pixel electrode PXE9b may overlap the seventh pixel circuit PC7b in a plan view, and a second portion extending from the first portion of the ninth pixel electrode PXE9b in the diagonal direction of the first direction DR1 and the second direction DR2 may overlap the ninth pixel circuit PC9b in a plan view.

The tenth pixel electrode PXE10b may be electrically connected to the tenth pixel circuit PC10b through the seventh connection electrode CNE7b. For example, the tenth pixel electrode PXE10b may contact the seventh connection electrode CNE7b through a contact hole penetrating the first via insulating layer in the thickness direction (e.g., the third direction DR3). In one or more embodiments, in a plan view, the shape of the fourth pixel electrode PXE4b may be substantially the same as the shape of the tenth pixel electrode PXE10b.

In one or more embodiments, the tenth pixel electrode PXE10b may overlap in a plan view each of the tenth pixel circuit PC10b and the eleventh pixel circuit PC11b. For example, a first portion of the tenth pixel electrode PXE10b may overlap the eleventh pixel circuit PC11b in a plan view, and a second portion extending from the first portion of the tenth pixel electrode PXE10b in an opposite direction in the first direction DR1 and in a diagonal direction in the second direction DR2 may overlap the tenth pixel circuit PC10b in a plan view.

The eleventh pixel electrode PXE11b may include a fifth main portion PXE11-1b and a fifth extending portion PXE11-2b. In one or more embodiments, the fifth main portion PXE11-1b may overlap each of the ninth pixel circuit PC9b and the tenth pixel circuit PC10b in a plan view.

In one or more embodiments, the fifth extending portion PXE11-2b may overlap each of the second pixel circuit PC2b and the sixth pixel circuit PC6b in a plan view. For example, in one or more embodiments, the fifth extending portion PXE11-2b may extend from the fifth main portion PXE11-1b in the first direction DR1 and may overlap each of the second pixel circuit PC2b and the sixth pixel circuit PC6b in a plan view.

In an embodiment, the fifth extending portion PXE11-2b may overlap the eighth connection electrode CNE8b in a plan view. For example, the fifth extending portion PXE11-2b may contact the eighth connection electrode CNE8b through a contact hole penetrating the first via insulating layer in the thickness direction (e.g., the third direction DR3). Accordingly, the eleventh pixel electrode PXE11b may be electrically connected to the eleventh pixel circuit PC11b via the eighth connection electrode CNE8b.

In one or more embodiments, the twelfth pixel electrode PXE12b may overlap each of the twelfth pixel circuit PC12b and the eighth pixel circuit PC8b in a plan view. In one or more embodiments, the twelfth pixel electrode PXE12b may overlap the fifth connection electrode CNE5b in a plan view.

In one or more embodiments, the fifth pixel electrode PXE5b and the sixth pixel electrode PXE6b may have a zigzag shape along the first direction DR1. Specifically, when the centers of the plurality of fifth pixel electrodes and the plurality of sixth pixel electrodes disposed along the first direction DR1 are connected in a plan view, a first virtual line LN1 connecting the centers may be zigzag based on the first direction DR1.

In one or more embodiments, the eleventh pixel electrode PXE11b and the twelfth pixel electrode PXE12b may have a zigzag shape along the first direction DR1. Specifically, when the centers of each of the plurality of eleventh pixel electrodes and the plurality of twelfth pixel electrodes disposed along the first direction DR1 are connected in a plan view, the second virtual line LN2 connecting the centers may be zigzag based on the first direction DR1. In one or more embodiments, the first virtual line LN1 and the second virtual line LN2 may be symmetrical based on a line that is parallel along the first direction DR1 and where the Nth row R(N) and the N+1th row R(N+1) adjoin to each other.

The first auxiliary electrode AXE1b may overlap each of the ninth pixel circuit PC9b and the tenth pixel circuit PC10b in a plan view. For example, the first auxiliary electrode AXE1b may be disposed along the second direction DR2 on the ninth pixel circuit PC9b and the tenth pixel circuit PC10b. Specifically, in a plan view, the first auxiliary electrode AXE1b may be disposed in an opposite direction from the fifth pixel electrode PXE5b in the second direction DR2 and may be disposed in the second direction DR2 from the eleventh pixel electrode PX11b. In other words, components of the pixel electrode layer PXLb disposed along the columns in which the ninth pixel circuit PC9b and the tenth pixel circuit PC10b are disposed may be repeatedly disposed along the second direction DR2 in an order of the first auxiliary electrode AXE1b, the fifth pixel electrode PXE5b, and the eleventh pixel electrode PX11b.

The second auxiliary electrode AXE2b may overlap each of the second pixel circuit PC2b and the sixth pixel circuit PC6b in a plan view. For example, the second auxiliary electrode AXE2b may be disposed along the second direction DR2 on the second pixel circuit PC2b and the sixth pixel circuit PC6b. Specifically, in a plan view, the second auxiliary electrode AXE2b may be disposed in the second direction DR2 from the sixth pixel electrode PXE6b adjacent to the second auxiliary electrode AXE2b and may be disposed in the second direction DR2 from the twelfth pixel electrode PX12b adjacent to the second auxiliary electrode AXE2b. In other words, components of the pixel electrode layer PXLb disposed along the columns in which the second pixel circuit PC2b and the sixth pixel circuit PC6b are disposed may be repeatedly disposed along the second direction DR2 in an order of the sixth pixel electrode PXE6b, the second auxiliary electrode AXE2b, and the twelfth pixel electrode PX12b. In one or more embodiments, the pixel defining layer PDL may entirely cover the upper surface of each of the plurality of second auxiliary electrodes.

In one or more embodiments, in a plan view, a shape of the first auxiliary electrode AXE1b and a shape of the second auxiliary electrode AXE2b may be substantially a same. In one or more embodiments, in a plan view, a size of the first auxiliary electrode AXE1b and a size of the second auxiliary electrode AXE2b may be substantially a same. However, a relationship between the first auxiliary electrode AXE1b and the second auxiliary electrode AXE2b according to the present disclosure may not be necessarily limited thereto.

However, arrangement, shape, size, and/or the like, of the first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, the eighth connection electrode CNE8, the ninth connection electrode CNE9, the tenth connection electrode CNE10, the eleventh connection electrode CNE11, and the twelfth connection electrode CNE12 according to the present disclosure may be shown as examples and may be not necessarily limited thereto.

However, number, shape, size, arrangement, and/or the like, of the connection electrodes included in the pixel circuit layer PXCb according to the present disclosure may be shown as examples and may be not necessarily limited thereto. For example, the first pixel circuit PC1b may include a connection electrode that overlaps and is electrically connected to the first pixel electrode PXE1b in a plan view, the sixth pixel circuit PC6b may include a connection electrode that overlaps and is electrically connected to the sixth pixel electrode PXE6b in a plan view, the seventh pixel circuit PC7b may include a connection electrode that overlaps and is electrically connected to the seventh pixel electrode PXE7b in a plan view, and the twelfth pixel circuit PC12b may include a connection electrode that overlaps and is electrically connected to the twelfth pixel electrode PXE12b in a plan view.

The light-emitting layer EMLb may include a first light-emitting layer EML1b, a second light-emitting layer EML2b, a third light-emitting layer EML3b, a fourth light-emitting layer EML4b, a fifth light-emitting layer EML5b, a sixth light-emitting layer EML6b, a seventh light-emitting layer EML7b, an eighth light-emitting layer EML8b, a ninth light-emitting layer EML9b, a tenth light-emitting layer EML10b, an eleventh light-emitting layer EML11b, and a twelfth light-emitting layer EML12b.

A hole penetrating the pixel defining layer PDL in a thickness direction (e.g., the third direction DR3) may include a first hole H1b, a second hole H2b, a third hole H3b, a fourth hole H4b, a fifth hole H5b, a sixth hole H6b, a seventh hole H7b, an eighth hole H8b, a ninth hole H9b, a tenth hole H10b, an eleventh hole H11b, a twelfth hole H12b, and a thirteenth hole H13b. The light-emitting layer EMLb and the hole may be substantially the same as or similar to the light-emitting layer EML and the holes of FIG. 8 except for shape, size, and location.

In one or more embodiments, a pixel defining layer (e.g., the pixel defining layer PDL of FIG. 9) covering the first auxiliary electrode AXE1b may define the thirteenth hole H13b exposing a portion of an upper surface of the first auxiliary electrode AXE1b.

In one or more embodiments, a number of the thirteenth holes H13b may be equal to a number of the first auxiliary electrode AXE1b. For example, the plurality of first auxiliary electrodes may be disposed along the first direction DR1 and the second direction DR2, and the thirteenth hole H13b may be located at each location where each of the plurality of first auxiliary electrodes is disposed.

In another embodiment, the number of the thirteenth holes H13b may be less than the number of the first auxiliary electrodes AXE1b. For example, the thirteenth hole H13b may be located at each location where each of the pixel electrodes of some of the plurality of first auxiliary electrodes AXE1b is disposed. For example, one of the thirteenth hole H13b may be disposed at each of two or more first auxiliary electrodes AXE1b that are adjacent to each other in the first direction DR1 or the second direction DR2.

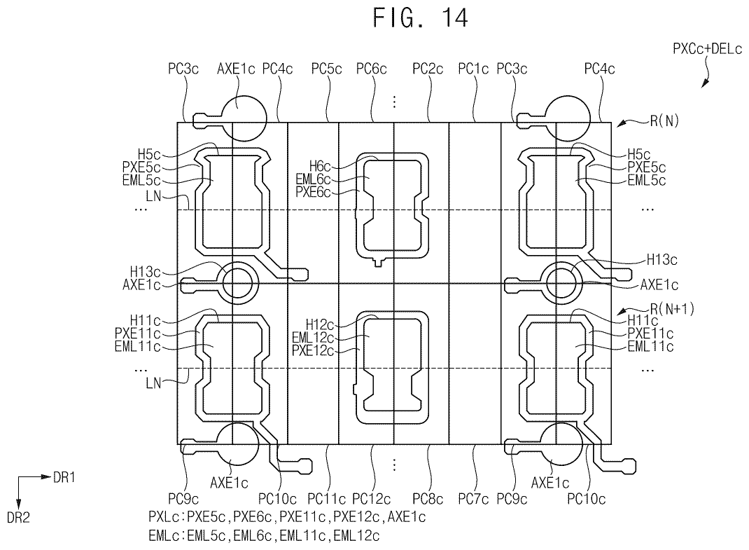

FIG. 14 is a plan view explaining for another example of an arrangement of a pixel electrode and an auxiliary electrode of FIG. 12.

The display device described with reference to FIG. 14 may be substantially the same as or similar to the display device described with reference to FIGS. 11, 12, and 13, except for an arrangement of a first auxiliary electrode AXE1c, a fifth pixel electrode PXE5c, a sixth pixel electrode PXE6c, a eleventh pixel electrode PXE11c, and a twelfth pixel electrode PXE12c.

Hereinafter, any content overlapping with the content described with reference to FIGS. 11, 12, and, 13 may be omitted or briefly described.

Referring to FIG. 14, a pixel electrode layer PXLc may include a fifth pixel electrode PXE5c, a sixth pixel electrode PXE6c, a eleventh pixel electrode PXE11c, a twelfth pixel electrode PXE12c, and a first auxiliary electrode AXE1c. In the present disclosure, the first auxiliary electrode AXE1c or the plurality of first auxiliary electrodes may be referred to as auxiliary electrodes or the plurality of first auxiliary electrodes.

In one or more embodiments, the fifth pixel electrode PXE5c and the sixth pixel electrode PXE6c may be disposed in a line along the first direction DR1. Specifically, when the centers of the plurality of fifth pixel electrodes and the plurality of sixth pixel electrodes disposed along the first direction DR1 are connected in a plan view, the virtual line LN connecting the centers may be parallel to the first direction DR1.

In one or more embodiments, the eleventh pixel electrode PXE11c and the twelfth pixel electrode PXE12c may be disposed in a line along the first direction DR1. Specifically, when the centers of each of the plurality of eleventh pixel electrodes and the plurality of twelfth pixel electrodes disposed along the first direction DR1 are connected in a plan view, the virtual line LN connecting the centers may be parallel to the first direction DR1.

In one or more embodiments, the first auxiliary electrode AXE1c may overlap each of the third pixel circuit PC3c, the fourth pixel circuit PC4c, the ninth pixel circuit PC9c, and the tenth pixel circuit PC10c in a plan view. In one or more embodiments, the first auxiliary electrode AXE1c may be disposed in the second direction DR2 or in the opposite direction of the second direction DR2 from the fifth pixel electrode PXE5c. In one or more embodiments, the first auxiliary electrode AXE1c may be disposed in the second direction DR2 or in the opposite direction of the second direction DR2 from the eleventh pixel electrode PXE11c.

In one or more embodiments, the first auxiliary electrode AXE1c may be repeatedly disposed along the second direction DR2 in multiple numbers. For example, a plurality of first auxiliary electrodes may be repeatedly disposed along the second direction DR2.

In one or more embodiments, in a plan view, the shape of each of the plurality of first auxiliary electrodes may be substantially a same. However, the shape of each of the plurality of first auxiliary electrodes according to the present disclosure may not be necessarily limited thereto.

In one or more embodiments, components of the pixel electrode layers PXLc disposed along columns in which the third pixel circuit PC3c and the fourth pixel circuit PC4c are disposed may be disposed along the second direction DR2 in an order of the first auxiliary electrode AXE1c, the fifth pixel electrode PXE5c, the first auxiliary electrode AXE1c, and the eleventh pixel electrode PXE11c. In one or more embodiments, in a plan view, no auxiliary electrode may be disposed between the sixth pixel electrode PXE6c and the twelfth pixel electrode PXE12c. Accordingly, a space in which the second extending portion PXE2-2b may pass over each of the second pixel circuit PC2c and the sixth pixel circuit PC6c may be easily secured.

The light-emitting layer EMLc may include a fifth light-emitting layer EML5c, a sixth light-emitting layer EML6c, an eleventh light-emitting layer EML11c, and a twelfth light-emitting layer EML12c. Holes penetrating the pixel defining layer (e.g., the pixel defining layer PDL of FIG. 9) in the thickness direction (e.g., the third direction DR3) may include a fifth hole H5c, a sixth hole H6c, an eleventh hole H11c, a twelfth hole H12c, and a thirteenth hole H13c. The light-emitting layer EMLc and the hole may be substantially the same as or similar to the light-emitting layer EMLb and the hole of FIG. 12 except for shape, size, and location.

In one or more embodiments, the thirteenth hole H13c is defined in the pixel defining layer covering the first auxiliary electrode AXE1c, and the thirteenth hole H13c may expose a portion of the upper surface of the first auxiliary electrode AXE1c.

In one or more embodiments, the thirteenth hole H13c may be defined in the pixel defining layer PDL covering the upper portions of some of the plurality of first auxiliary electrodes. The thirteenth hole H13c may not be defined in the pixel defining layer PDL covering upper portions of the remaining electrodes from among the plurality of first auxiliary electrodes.

In one or more embodiments, a number of thirteenth holes H13c may be equal to a number of first auxiliary electrodes AXE1c. For example, the plurality of first auxiliary electrodes may be disposed along the first direction DR1 and the second direction DR2, and the thirteenth hole H13c may be located at each location where each of the plurality of second auxiliary electrodes is disposed.

In another embodiment, the number of thirteenth holes H13c may be less than the number of first auxiliary electrodes AXE1c. For example, the thirteenth hole H13c may be located at each location where some of the pixel electrodes from among the plurality of first pixel electrodes are disposed. For example, one thirteenth hole H13c may be disposed at two or more auxiliary electrodes that are adjacent to each other in the first direction DR1 or the second direction DR2.

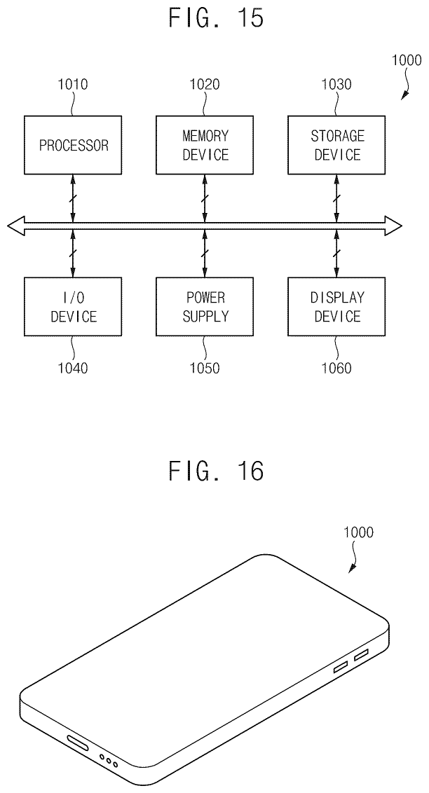

FIG. 15 is a block diagram illustrating an electronic device according to one or more embodiments. FIG. 16 is a view illustrating an example being implemented as a smart phone.

Referring to FIGS. 15 and 16, the electronic device 1000 may include a processor 1010, a memory device 1020, a storage device 1030, an input/output device 1040, a power supply 1050, and a display device 1060. The display device 1060 included in the electronic device 1000 may be the display device 1 of FIG. 1. In addition, the electronic device 1010 may further include several ports that may communicate with a video card, a sound card, a memory card, a USB device, or the like, or may communicate with other systems.

The processor 1010 may control the display device 1060. For example, the processor 1010 may perform specific calculations or tasks. According to one or more embodiments, the processor 1010 may be a microprocessor, a central processing unit, an application processor, or the like. The processor 1010 may be connected to other components via an address bus, a control bus, a data bus, or the like. According to one or more embodiments, the processor 1010 may also be connected to an expansion bus such as a Peripheral Component Interconnect (PCI) bus. The processor 1010 may output input image data and an input control signal (e.g., the input image data IMG and the input control signal CONT of FIG. 1) to the driving controller of FIG. 1.

The memory device 1020 may store data necessary for the operation of the electronic device 1000. For example, the memory device 1020 may include a nonvolatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and/or a volatile memory device such as a dynamic random access memory (DRAM) device, a static random access memory (SRAM) device, a mobile DRAM device, and the like.

The storage device 1030 may include a solid state drive (SSD), a hard disk drive (HDD), a CD-ROM, or the like. The input/output device 1040 may include input means such as a keyboard, a keypad, a touchpad, a touchscreen, a mouse, or the like., and output means such as a speaker, a printer, or the like. According to one or more embodiments, a display device 1060 may be included in the input/output device 1040. The power supply 1050 may supply power necessary for the operation of the electronic device 1000. The display device 1060 may be connected to other components through the buses or other communication links. The display device 1060 may be driven based on the input image data output from the processor 1010 and the input control signal.

In one or more embodiments, as illustrated in FIG. 16, the electronic device 1000 may be implemented as a smartphone. However, the smartphone is example of the electronic device 1000, and the electronic device 1000 according to embodiments of the present disclosure may not be limited thereto. For example, the electronic device 1000 may be implemented as a television, a mobile phone, a video phone, a smart pad, a smart watch, a tablet PC, a vehicle display, a computer monitor, a notebook computer, a head-mounted display device, or the like. In addition, the electronic device 1000 may be a television, a monitor, a notebook computer, or a tablet. In addition, the electronic device 1000 may be an automobile.

The device according to the embodiments of the present disclosure may be applied to a display device included in a computer, a notebook, a mobile phone, a smartphone, a smart pad, a PMP, a PDA, an MP3 player, or the like.

Although the devices according to the embodiments of the present disclosure have been described with reference to the drawings, the illustrated embodiments are examples, and may be modified and changed by a person having ordinary knowledge in the relevant technical field without departing from the technical spirit described in the following claims and their equivalents.

What is claimed is:

1. A display device comprising:
a pixel circuit layer comprising a first pixel circuit, a second pixel circuit, and a third pixel circuit that are disposed in a same row;
a first light-emitting element configured to emit light of a first color, and comprising:
a first pixel electrode on the pixel circuit layer and electrically connected to the first pixel circuit; and
a first light-emitting layer on the first pixel electrode;
a second light-emitting element configured to emit light of the first color, and comprising:
a second pixel electrode on the pixel circuit layer and electrically connected to the second pixel circuit; and
a second light-emitting layer on the second pixel electrode;
a third light-emitting element configured to emit light of a second color different from the first color, and comprising:
a third pixel electrode on the pixel circuit layer, electrically connected to the third pixel circuit, and overlapping each of the first pixel circuit, the second pixel circuit, and the third pixel circuit in a plan view; and
a third light-emitting layer on the third pixel electrode;
a first write gate line extending along a first direction in the pixel circuit layer, and configured to provide a first write gate signal to the first pixel circuit and the third pixel circuit; and
a second write gate line extending along the first direction in the pixel circuit layer, and configured to provide a second write gate signal applied at a different timing from an application timing of the first write gate signal to the second pixel circuit.

2. The display device of claim 1, wherein the third pixel electrode comprises:
a first main portion overlapping the third pixel circuit in a plan view; and
a first extending portion extending from the first main portion, and overlapping each of the first pixel circuit, the second pixel circuit, and the third pixel circuit in a plan view.

3. The display device of claim 2, wherein the pixel circuit layer further comprises:
a fourth pixel circuit electrically connected to the second write gate line;
a fifth pixel circuit electrically connected to the first write gate line; and
a sixth pixel circuit electrically connected to the second write gate line.

4. The display device of claim 3, wherein the second pixel circuit, the first pixel circuit, the third pixel circuit, the fourth pixel circuit, the fifth pixel circuit, and the sixth pixel circuit are repeatedly arranged along the first direction in an order of the second pixel circuit, the first pixel circuit, the third pixel circuit, the fourth pixel circuit, the fifth pixel circuit, and the sixth pixel circuit.

5. The display device of claim 3, further comprising:
a fourth light-emitting element configured to emit light of the second color, and comprising:
a fourth pixel electrode on the pixel circuit layer, and electrically connected to the fourth pixel circuit; and
a fourth light-emitting layer on the fourth pixel electrode;
a fifth light-emitting element configured to emit light of a third color different from the first color and the second color, and comprising:
a fifth pixel electrode disposed on the pixel circuit layer, and electrically connected to the fifth pixel circuit; and
a fifth light-emitting layer on the fifth pixel electrode; and
a sixth light-emitting element configured to emit light of the third color, and comprising:
a sixth pixel electrode on the pixel circuit layer, and electrically connected to the sixth pixel circuit; and
a sixth light-emitting layer on the sixth pixel electrode.

6. The display device of claim 5, wherein the fifth pixel electrode comprises:
a second main portion overlapping the sixth pixel circuit in a plan view; and
a second extending portion extending from the second main portion, and overlapping each of the fourth pixel circuit and the fifth pixel circuit.

7. The display device of claim 6, wherein the second extending portion of the fourth pixel electrode is spaced from the fifth pixel electrode in a plan view, and extends along at least a portion of the fifth pixel electrode.

8. The display device of claim 5, wherein the sixth pixel electrode comprises:
a third main portion overlapping each of the first pixel circuit adjacent to the sixth pixel circuit, and the second pixel circuit; and
a third extending portion extending from the third main portion, and overlapping each of the second pixel circuit and the sixth pixel circuit.

9. The display device of claim 8, wherein the first extending portion of the third pixel electrode is spaced from the third main portion of the sixth pixel electrode in a plan view, and extends along at least a portion of the third main portion.

10. The display device of claim 5, wherein further comprising:
a plurality of first auxiliary electrodes on the pixel circuit layer, adjacent to the sixth pixel electrode, and arranged along a second direction crossing the first direction; and
a pixel defining layer on the first auxiliary electrodes,
wherein a hole is defined in the pixel defining layer, and the hole exposes an upper surface of at least one of a first auxiliary electrode from among the plurality of the first auxiliary electrodes.

11. The display device of claim 10, further comprising:
a plurality of second auxiliary electrodes on the pixel circuit layer, adjacent to the fifth pixel circuit, and arranged along the second direction,
wherein the pixel defining layer covers an upper surface of each of the second auxiliary electrodes entirely.

12. The display device of claim 3, further comprising:
a first data line extending along a second direction crossing the first direction in the pixel circuit layer, and electrically connected to each of the first pixel circuit and the second pixel circuit;
a second data line extending along the second direction in the pixel circuit layer, and electrically connected to the third pixel circuit and the fourth pixel circuit; and
a third data line extending along the second direction in the pixel circuit layer, and electrically connected to the fifth pixel circuit and sixth pixel circuit.

13. The display device of claim 12, wherein the first data line is between the first pixel circuit and the second pixel circuit that are adjacent to each other, in a plan view,
wherein the second data line is between the third pixel circuit and the fourth pixel circuit that are adjacent to each other, in a plan view, and
wherein the third data line is between the fifth pixel circuit and the sixth pixel circuit that are adjacent to each other, in a plan view.

14. A display device comprising:
a pixel circuit layer comprising a first pixel circuit, a second pixel circuit spaced from the first pixel circuit in a first direction, a third pixel circuit, a fourth pixel circuit, a fifth pixel circuit, and a sixth pixel circuit that are located between the first pixel circuit and the second pixel circuit and arranged along the first direction orderly;
a first light-emitting element configured to emit light of a first color, and comprising:
a first pixel electrode on the pixel circuit layer and electrically connected to the first pixel circuit; and
a first light-emitting layer on the first pixel electrode;
a second light-emitting element configured to emit light of the first color, and comprising:
a second pixel electrode on the pixel circuit layer, electrically connected to the second pixel circuit, and overlapping each of the second pixel circuit, the fifth pixel circuit, and the sixth pixel circuit in a plan view; and
a second light-emitting layer on the second pixel electrode; and
a third light-emitting element configured to emit light of a second color different from the first color, and comprising:
a third pixel electrode on the pixel circuit layer and electrically connected to the third pixel circuit; and
a third light-emitting layer on the third pixel electrode.

15. The display device of claim 14, wherein the second pixel electrode comprises:
a main portion overlapping the second pixel circuit in a plan view; and
an extending portion extending from the main portion along the first direction, and overlapping each of the second pixel circuit, the fifth pixel circuit, and the sixth pixel circuit in a plan view.

16. The display device of claim 14, further comprising:
a first write gate line extending along the first direction in the pixel circuit layer, and configured to provide a first write gate signal to each of the first pixel circuit, the third pixel circuit, and the fifth pixel circuit; and
a second write gate line extending along the first direction in the pixel circuit layer, and configured to a second write gate signal applied at a different timing from an application timing of the first write gate signal to the second pixel circuit, the fourth pixel circuit, and the sixth pixel circuit.

17. The display device of claim 14, further comprising:
a first data line extending along a second direction crossing the first direction in the pixel circuit layer, and electrically connected to each of the first pixel circuit and the second pixel circuit;
a second data line extending along the second direction in the pixel circuit layer, and electrically connected to each of the third pixel circuit and the fourth pixel circuit; and
a third data line extending along the second direction in the pixel circuit layer, and electrically connected to each of the fifth pixel circuit and the sixth pixel circuit.

18. The display device of claim 14, further comprising:
a fourth light-emitting element configured to emit light of the second color, and comprising:
a fourth pixel electrode on the pixel circuit layer and electrically connected to the fourth pixel circuit; and
a fourth light-emitting layer on the fourth pixel electrode;
a fifth light-emitting element configured to emit light of a third color different from the first color and the second color, and comprising:
a fifth pixel electrode on the pixel circuit layer and electrically connected to the fifth pixel circuit; and
a fifth light-emitting layer on the fifth pixel electrode; and
a sixth light-emitting element configured to emit light of the third color, and comprising:
a sixth pixel electrode on the pixel circuit layer and electrically connected to the sixth pixel circuit; and
a sixth light-emitting layer on the sixth pixel electrode.

19. The display device of claim 18, further comprising:
a plurality of first auxiliary electrodes on the pixel circuit layer, adjacent to the fifth pixel electrode, and arranged along a second direction crossing the first direction;
a plurality of second auxiliary electrodes on the pixel circuit layer, adjacent to the sixth pixel electrode, and arranged along the second direction; and
a pixel defining layer on the first auxiliary electrodes and the second auxiliary electrodes,
wherein a hole is defined in the pixel defining layer, and the hole exposes an upper surface of at least one of a first auxiliary electrode among the first auxiliary electrodes,
wherein the pixel defining layer covers an upper surface of each of the second auxiliary electrodes entirely, and
wherein a virtual line connecting a center of the fifth pixel electrode and a center of the sixth pixel electrode has a zigzag shape along the first direction.

20. An electronic device comprising:
a processor configured to output an input image data and an input control signal; and
a display device configured to drive based on the input image data and the input control data, and the display device comprising:
a pixel circuit layer comprising a first pixel circuit, a second pixel circuit, and a third pixel circuit that are arranged in a same row;
a first light-emitting element configured to emit light of a first color, and comprising: a first pixel electrode on the pixel circuit layer and electrically connected to the first pixel circuit and a first light-emitting layer on the first pixel electrode;
a second light-emitting element configured to emit light of the first color comprising a second pixel electrode on the pixel circuit layer and electrically connected to the second pixel circuit and a second light-emitting layer on the second pixel electrode;
a third light-emitting element configured to emit light of a second color different from the first color, and comprising a third pixel electrode on the pixel circuit layer, electrically connected to the third pixel circuit, and overlapping each of the first pixel circuit, the second pixel circuit, and the third pixel circuit in a plan view and a third light-emitting layer on the third pixel electrode;
a first write gate line extending along a first direction in the pixel circuit layer, and configured to provide a first write gate signal to the first pixel circuit and the third pixel circuit; and
a second write gate line extending along the first direction in the pixel circuit layer, and configured to provide a second write gate signal applied at a different timing from an application timing of the first write gate signal to the second pixel circuit.
